(19) United States
(12) Patent Application Publication
(10) Pub. No.: US 2024/0421049 A1
(43) Pub. Date: Dec. 19, 2024

(54) SEMICONDUCTOR DEVICE AND SEMICONDUCTOR MODULE

(71) Applicant: ROHM CO., LTD., Kyoto-shi (JP)

(72) Inventor: Takeshi OKAMOTO, Kyoto-shi (JP)

(73) Assignee: ROHM CO., LTD., Kyoto-shi (JP)

(21) Appl. No.: 18/820,361

(22) Filed: Aug. 30, 2024

Related U.S. Application Data
(63) Continuation of application No. PCT/JP2022/047319, filed on Dec. 22, 2022.

(30) Foreign Application Priority Data
Mar. 4, 2022 (JP) 2022-033875

(51) Int. Cl. H01L 23/495; H01L 23/00; H01L 29/40; H01L 29/739

(52) U.S. Cl. CPC H01L 23/49562; H01L 23/49503; H01L 24/32; H01L 24/48; H01L 24/73; H01L 29/402; H01L 29/7395; H01L 2224/32225; H01L 2224/48247; H01L 2224/73265; H01L 2924/13055; H01L 2924/13091

(57) ABSTRACT

The semiconductor device includes a semiconductor chip that has a first principal surface, a withstand-voltage holding structure in a peripheral region in the first principal surface, a plurality of first conductive layers that are formed in the first principal surface, a second conductive layer overlaps with a space between the plurality of mutually adjacent first conductive layers in a plan view, and a protective layer that covers the plurality of first conductive layers and the second conductive layer.

### CROSS-REFERENCE TO RELATED APPLICATIONS

The present application is a continuation application of PCT Application No. PCT/JP2022/047319, filed on Dec. 22, 2022, which corresponds to Japanese Patent Application No. 2022-033875 filed on Mar. 4, 2022, with the Japan Patent Office, and the entire disclosure of each are incorporated herein by reference.

### TECHNICAL FIELD

The present disclosure relates to a semiconductor device and a semiconductor module.

### BACKGROUND ART

For example, the semiconductor device described in Japanese Unexamined Patent Application Publication No. 2021-158388 includes a semiconductor layer having a front surface, a rear surface and an end surface which extends in a direction intersecting the front surface, a p-type body region that is formed at a front surface portion of the semiconductor layer, an n⁺ type source region that is formed in a front surface portion of the body region, an n⁻ type drift region that is formed so as to be exposed in the rear surface of the semiconductor layer and separated from the source region by the body region, a gate electrode that opposes the body region across a gate insulating film, a drain electrode that forms a Schottky junction with the drift region in the rear surface and has a peripheral edge at a position away further internally from the end surface of the semiconductor layer, and a rear surface termination structure that is formed at the rear surface side and arranged so as to overlap with a peripheral edge portion of the drain electrode.

### BRIEF DESCRIPTION OF DRAWINGS

FIG. 1 is a schematic external view of a semiconductor device according to a preferred embodiment of the present disclosure.

FIG. 2 is a schematic plan view of an element chip that is shown in FIG. 1.

FIG. 3 is a cross sectional view taken along line III-III shown in FIG. 2.

FIG. 4A and FIG. 4B are respectively a schematic cross sectional view of the element chip in an outer region and a schematic cross sectional view of that in an element forming region.

FIG. 5 is a schematic cross sectional view for describing a structure of an emitter lead-out electrode layer and that of a gate lead-out electrode layer.

FIG. 6 is a drawing for schematically showing a flat surface pattern of a sealing conductive layer.

FIG. 7 is a drawing for schematically showing a flat surface pattern of the sealing conductive layer.

FIG. 8A and FIG. 8B are drawings for showing some of the steps of manufacturing the semiconductor device.

FIG. 9A and FIG. 9B are drawings respectively for showing a step subsequent to that of FIG. 8A and a step subsequent to that of FIG. 8B.

FIG. 10A and FIG. 10B are drawings respectively for showing a step subsequent to that of FIG. 9A and a step subsequent to that of FIG. 9B.

FIG. 11A and FIG. 11B are drawings respectively for showing a step subsequent to that of FIG. 10A and a step subsequent to that of FIG. 10B.

FIG. 12A and FIG. 12B are drawings respectively for showing a step subsequent to that of FIG. 11A and a step subsequent to that of FIG. 11B.

FIG. 13A and FIG. 13B are drawings respectively for showing a step subsequent to that of FIG. 12A and a step subsequent to that of FIG. 12B.

FIG. 14A and FIG. 14B are drawings respectively for showing a step subsequent to that of FIG. 13A and a step subsequent to that of FIG. 13B.

FIG. 15A and FIG. 15B are drawings respectively for showing a step subsequent to that of FIG. 14A and a step subsequent to that of FIG. 14B.

FIG. 16A and FIG. 16B are drawings respectively for showing a step subsequent to that of FIG. 15A and a step subsequent to that of FIG. 15B.

FIG. 17A and FIG. 17B are drawings respectively for showing a step subsequent to that of FIG. 16A and a step subsequent to that of FIG. 16B.

FIG. 18A and FIG. 18B are respectively a schematic cross sectional view of the element chip in the outer region and a schematic cross sectional view of that in the element forming region.

FIG. 19A and FIG. 19B are respectively a schematic cross sectional view of the element chip in the outer region and a schematic cross sectional view of that in the element forming region.

FIG. 20A and FIG. 20B are respectively a schematic cross sectional view of the element chip in the outer region and a schematic cross sectional view of that in the element forming region.

FIG. 21 is a drawing for schematically showing a flat surface pattern of the sealing conductive layer.

FIG. 22 is a drawing for schematically showing a flat surface pattern of the sealing conductive layer.

FIG. 23A and FIG. 23B are respectively a schematic cross sectional view of the element chip in the outer region and a schematic cross sectional view of that in the element forming region.

FIG. 24A and FIG. 24B are respectively a schematic cross sectional view of the element chip in the outer region and a schematic cross sectional view of that in the element forming region.

FIG. 25 is a schematic cross sectional view of the element chip in the outer region.

FIG. 26A and FIG. 26B are respectively a schematic cross sectional view of the element chip in the outer region and a schematic cross sectional view of that in the element forming region.

FIG. 27 is a schematic external view of the semiconductor module according to a preferred embodiment of the present disclosure.

FIG. 28 is a circuit diagram for showing an electrical structure of a semiconductor module that is shown in FIG. 27.

### DESCRIPTION OF EMBODIMENTS

Next, a preferred embodiment of the present disclosure will be described in detail by referring to the attached drawings.

### [Entire Configuration of Semiconductor Device 1]

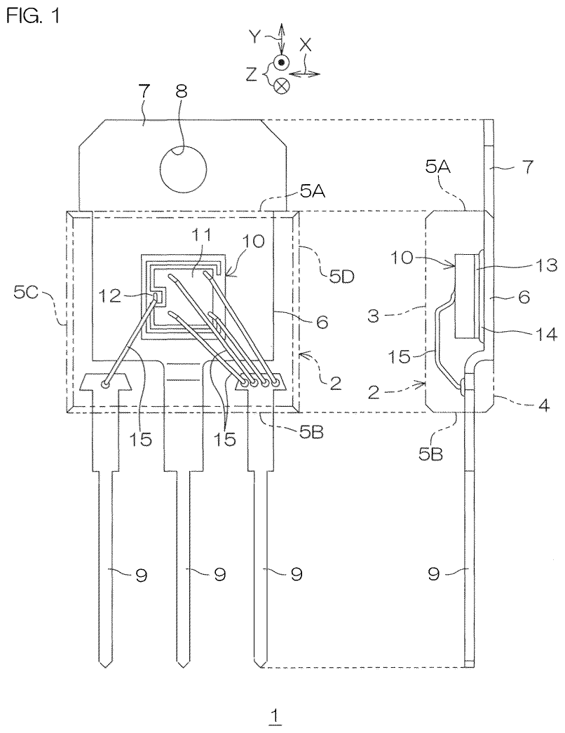

FIG. 1 is a schematic external view of a semiconductor device 1 according to a preferred embodiment of the present disclosure. In FIG. 1, an inner structure of a package main body 2 is viewed through by indicating the package main body 2 with a single dot & dash line.

The semiconductor device 1 is an IGBT discrete semiconductor that includes the package main body 2 in a rectangular parallelepiped shape. The package main body 2 is formed of a mold resin. The package main body 2 may include a matrix resin (for example, epoxy resin), a plurality of fillers and a plurality of flexible particles (flexible agent). The package main body 2 has a first surface 3 at one side, a second surface 4 at the other side, and first to fourth side walls 5A to 5D that connect the first surface 3 and the second surface 4.

The first surface 3 and the second surface 4 are each formed in a quadrangle shape in a plan view as viewed from their normal direction Z. The first side wall 5A and the second side wall 5B extend in a first direction X and oppose in a second direction Y that intersects the first direction X. The third side wall 5C and the fourth side wall 5D extend in the second direction Y and oppose in the first direction X.

The semiconductor device 1 includes a metal plate 6 (conductive plate) that is arranged inside the package main body 2. The metal plate 6 may be referred to as a “die pad.” The metal plate 6 is formed in a quadrangle shape (specifically, in a rectangular shape) in a plan view. The metal plate 6 includes a lead-out plate portion 7 that is led out from the first side wall 5A to the outside of the package main body 2. The lead-out plate portion 7 has a circular through hole 8. The metal plate 6 may be exposed from the second surface 4.

The semiconductor device 1 includes a plurality of (in this preferred embodiment, three) lead terminals 9 that are led out to the outside from the inside of the package main body 2. The plurality of lead terminals 9 are arranged at the second side wall 5B side. The plurality of lead terminals 9 are each formed as a band extending in a direction that intersects the second side wall 5B (that is, second direction Y). Of the plurality of lead terminals 9, the lead terminals 9 at both sides are arranged at an interval from the metal plate 6, and the lead terminal 9 in the center is integrally formed with the metal plate 6. An arrangement of the lead terminal 9 connected to the metal plate 6 is arbitrary.

The semiconductor device 1 includes an element chip 10 that is arranged on the metal plate 6 inside the package main body 2. The element chip 10 has an emitter terminal electrode 11 and a gate terminal electrode 12 at the front surface side and has a collector terminal electrode 13 at the rear surface side. The element chip 10 is arranged on the metal plate 6 in a posture that the collector terminal electrode 13 opposes the metal plate 6 and electrically connected to the metal plate 6.

The semiconductor device 1 includes a conductive adhesive agent 14 that is interposed between the collector terminal electrode 13 and the metal plate 6 and joins the element chip 10 to the metal plate 6. The conductive adhesive agent 14 may include a solder or a metal paste. The solder may be a lead-free solder. The metal paste may contain at least one among Au, Ag and Cu. An Ag paste may consist of an Ag sintered paste. The Ag sintered paste consists of a paste in which Ag particles of nano or micro size are added to an organic solvent.

The semiconductor device 1 includes at least one conducting wire 15 (conductive connecting member) (in this preferred embodiment, a plurality of them) that is electrically connected to the lead terminal 9 and the element chip 10 inside the package main body 2. In this preferred embodiment, the conducting wire 15 consists of a metal wire (that is, bonding wire). The conducting wire 15 may include at least one among a gold wire, a copper wire and an aluminum wire. As a matter of course, the conducting wire 15 may consist of a metal plate such as a metal clip in place of the metal wire.

At least, the one conducting wire 15 (in this preferred embodiment, one) is electrically connected to the gate terminal electrode 12 and the lead terminal 9. At least, the one conducting wire 15 (in this preferred embodiment, four) is electrically connected to the emitter terminal electrode 11 and the lead terminal 9.

### [Entire Configuration of Element Chip 10]

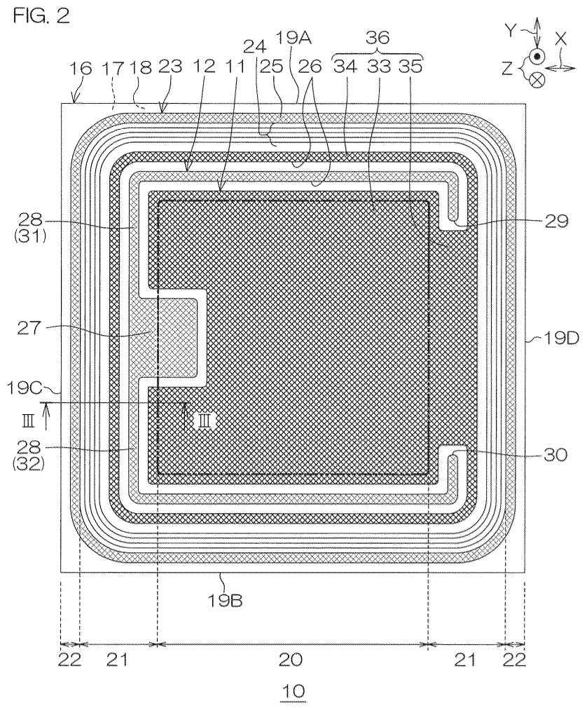

FIG. 2 is a schematic plan view of the element chip 10 shown in FIG. 1.

With reference to FIG. 2, the element chip 10 includes a semiconductor chip 16 that is formed as a chip in a quadrangle shape in a plan view. The semiconductor chip 16 includes a first principal surface 17, a second principal surface 18 at the opposite side of the first principal surface 17 and first to fourth side surfaces 19A, 19B, 19C, 19D that connect the first principal surface 17 and the second principal surface 18.

The first principal surface 17 and the second principal surface 18 are each formed in a quadrangle shape as viewed in their normal direction Z in a plan view. The first side surface 19A and the second side surface 19B extend in the first direction X and oppose in the second direction Y that intersects the first direction X. The third side surface 19C and the fourth side surface 19D extend in the second direction Y and oppose in the first direction X.

In the semiconductor chip 16, an element forming region 20 as well as an outer region 21 and a scribe region 22 that are regions outside the element forming region 20 are set.

The element forming region 20 is set in a central region of the semiconductor chip 16 as viewed in a normal direction of the first principal surface 17 of the semiconductor chip 16 in a plan view. The outer region 21 is set in a region outside the element forming region 20. The scribe region 22 is set in a region outside the outer region 21.

In this preferred embodiment, the element forming region 20 is a region in which an IGBT (Insulated Gate Bipolar Transistor) is formed. The element forming region 20 may be referred to as an active region. The element forming region 20 is set in a quadrangle shape in a plan view that has four sides parallel to the first to fourth side surfaces 19A, 19B, 19C, 19D of the semiconductor chip 16 in a plan view. The element forming region 20 is set at an interval inside the semiconductor chip 16 from the first to fourth side surfaces 19A, 19B, 19C, 19D of the semiconductor chip 16.

The outer region 21 is a region that demarcates an outer circumference of the element forming region 20. The outer region 21 is set in an endless shape (quadrilateral annular shape in a plan view) that surrounds the element forming region 20 in a region between the first to fourth side surfaces 19A, 19B, 19C, 19D of the semiconductor chip 16 and the element forming region 20. The outer region 21 may be defined as an outer circumference region of the semiconductor chip 16 in view of the fact that it forms an outer circumference of the element forming region 20.

The scribe region 22 is a region through which a cutting member such as a dicing blade passes when manufactured. The scribe region 22 is set in an endless shape (quadrilateral annular shape in a plan view) that surrounds the outer region 21 in a region between the first to fourth side surfaces 19A, 19B, 19C, 19D of the semiconductor chip 16 and the outer region 21.

A front surface electrode 23 is formed on the first principal surface 17 of the semiconductor chip 16. The front surface electrode 23 may include the gate terminal electrode 12, the emitter terminal electrode 11, a field plate electrode 24 and an equipotential electrode 25. The gate terminal electrode 12, the emitter terminal electrode 11, the field plate electrode 24 and the equipotential electrode 25 are each electrically insulated by an insulating region 26 that fringes them.

The gate terminal electrode 12 is mainly formed in the outer region 21. The gate terminal electrode 12 includes a gate pad 27 and a gate finger 28. The gate pad 27 is formed along a central region of the second side surface 19C in a plan view. In this preferred embodiment, the gate pad 27 is formed in a quadrangle shape in a plan view. The gate pad 27 is led out from the outer region 21 to the inside of the element forming region 20 and crosses a boundary portion between the element forming region 20 and the outer region 21.

The gate finger 28 is led out from the gate pad 27 in the outer region 21 and surrounds the element forming region 20 in three directions. The gate finger 28 has a pair of open ends 29, 30 at the fourth side surface 19D side. The gate finger 28 extends as a band in a region between the pair of open ends 29, 30 and the gate pad 27. More specifically, the gate finger 28 includes a first gate finger 31 and a second gate finger 32.

The first gate finger 31 is led out from an end portion of the gate pad 27 at the first side surface 19A side. The first gate finger 31 has the open end 29 at the fourth side surface 19D side. The first gate finger 31 extends as a band along the third side surface 19C and the first side surface 19A in a region between the gate pad 27 and the open end 29.

The second gate finger 32 is led out from an end portion of the gate pad 27 at the second side surface 19B side. The second gate finger 32 has the open end 30 at the fourth side surface 19D side. The second gate finger 32 extends as a band along the third side surface 19C and the second side surface 19B in a region between the gate pad 27 and the open end 30.

The emitter terminal electrode 11 includes an emitter pad 33, an emitter routing portion 34 and an emitter connecting portion 35.

The emitter pad 33 is formed inside a recessed region in a plan view that is demarcated by a peripheral edge of the gate pad 27 and a peripheral edge of the gate finger 28. The emitter pad 33 is formed in a recessed shape in a plan view along the peripheral edge of the gate pad 27 and the peripheral edge of the gate finger 28. The emitter pad 33 covers substantially an entire area of the element forming region 20 outside the gate pad 27. A peripheral edge of the emitter pad 33 is led out to the inside of the outer region 21 from the element forming region 20 and crosses a boundary portion between the element forming region 20 and the outer region 21.

The emitter routing portion 34 is formed in the outer region 21. The emitter routing portion 34 is routed as a band in a region outside the gate finger 28. In this preferred embodiment, the emitter routing portion 34 is formed in an endless shape (quadrilateral annular shape in a plan view) that surrounds the gate finger 28. The emitter routing portion 34 may be formed in a shape having an end that surrounds the gate finger 28.

The emitter connecting portion 35 is led out from the emitter pad 33. The emitter connecting portion 35 crosses a region between the pair of open ends 29, 30 of the gate finger 28 and is connected to the emitter routing portion 34. The emitter routing portion 34 is electrically connected to the emitter pad 33 via the emitter connecting portion 35.

The IGBT that is formed in the element forming region 20 includes an npn-type parasitic bipolar transistor due to its structure. An avalanche current that is produced in a region outside the element forming region 20 flows into the element forming region 20, by which the parasitic bipolar transistor is turned in an on state. In this case, control of the IGBT is made unstable, for example, by latch-up.

Thus, in this preferred embodiment, an avalanche current recovery structure 36 for recovering an avalanche current produced in a region outside the element forming region 20 is formed by the emitter terminal electrode 11 that includes the emitter pad 33, the emitter routing portion 34 and the emitter connecting portion 35. More specifically, the avalanche current that is produced in a region outside the element forming region 20 is recovered by the emitter routing portion 34. The recovered avalanche current is taken out from the emitter pad 33 via the emitter connecting portion 35. Thereby, it is possible to suppress the parasitic bipolar transistor from being turned to an on state by an unwanted current produced in a region outside the element forming region 20. It is, thereby, possible to suppress the latch-up, resulting in an increase in control stability of the IGBT.

The field plate electrode 24 is formed in the outer region 21. In FIG. 2, the field plate electrode 24 is indicated by a black line. The plurality of (four, in this preferred embodiment) field plate electrodes 24 are formed at an interval in the outer region 21. Each of the field plate electrodes 24 is routed as a band along the emitter routing portion 34. In this preferred embodiment, each of the field plate electrodes 24 is formed in an endless shape (quadrilateral annular shape in a plan view) that surrounds the emitter routing portion 34. At least one field plate electrode 24 may be formed in a shape having an end.

The equipotential electrode 25 is formed in the scribe region 22. The equipotential electrode 25 is routed as a band along the field plate electrode 24. In this preferred embodiment, the equipotential electrode 25 is formed in an endless shape (quadrilateral annular shape in a plan view) that surrounds the field plate electrode 24. The equipotential electrode 25 is formed as a so-called EQR (Equi-Potential Ring) electrode.

### [Inner Structure of Element Chip 10]

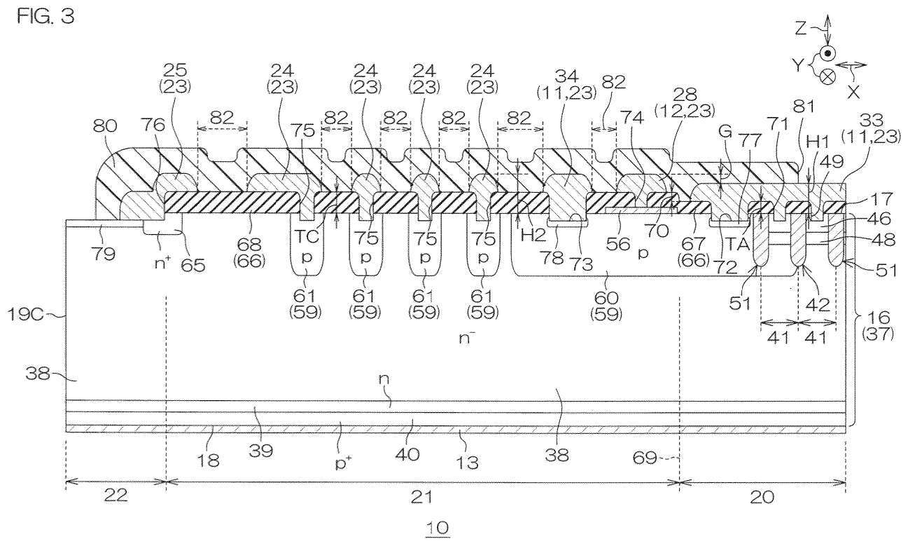

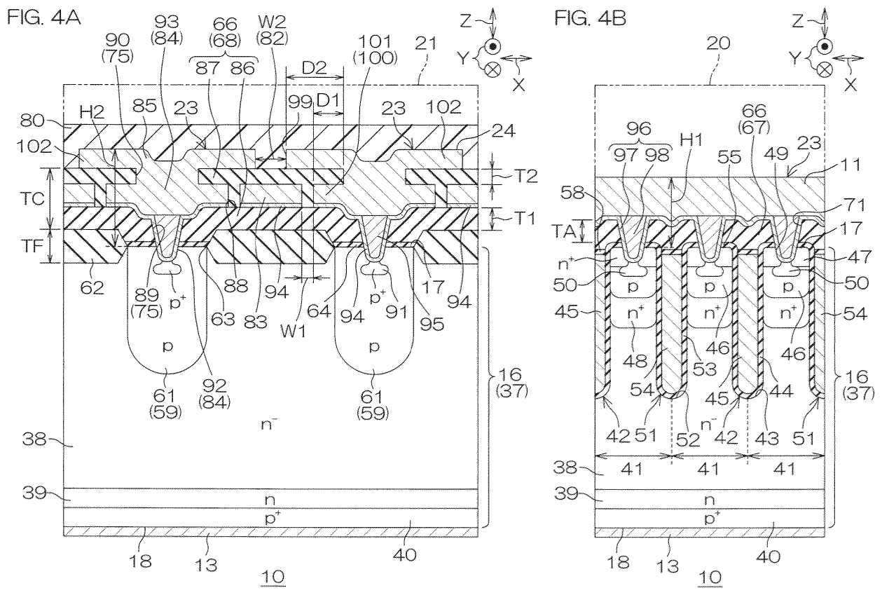

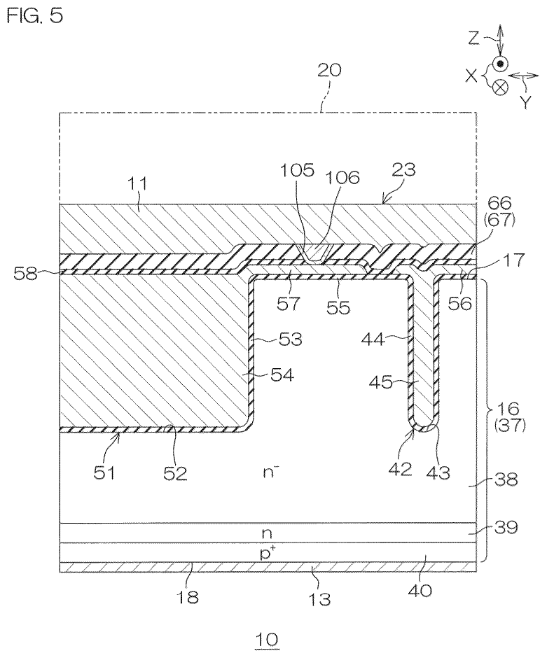

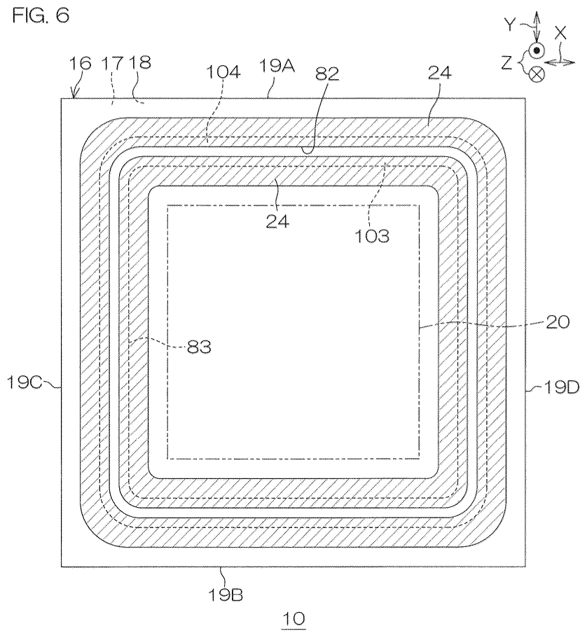

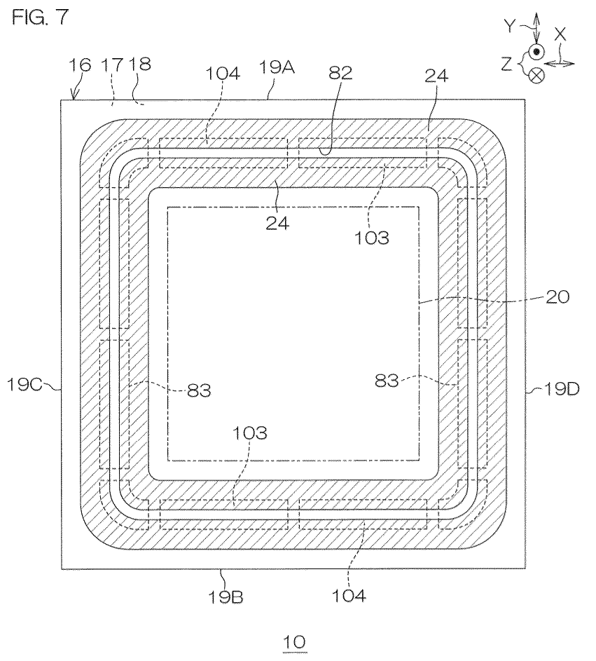

Next, an inner structure of the element chip 10 will be described specifically. FIG. 3 is a cross sectional view taken along line III-III shown in FIG. 2. FIG. 4A and FIG. 4B are respectively a schematic cross sectional view of the element chip 10 in the outer region 21 and a schematic cross sectional view of that in the element forming region 20. FIG. 5 is a schematic cross sectional view that describes a structure of the emitter lead-out electrode layer 57 and that of the gate lead-out electrode layer 56. FIG. 6 and FIG. 7 are each a drawing that schematically shows a flat surface pattern of a sealing conductive layer 83. It is noted in advance that, in the following description, a ratio relationship of dimensions (for example, thickness, width, length, etc.) of each constituent does not match a ratio relationship of the dimensions shown in FIG. 3 to FIG. 7. Also, in FIG. 3, for clarification, some of the constituents shown in FIG. 4A and FIG. 4B are omitted.

With reference to FIG. 3 to FIG. 5, the semiconductor chip 16 has a single layered structure that includes an n⁻ type semiconductor substrate 37. In this preferred embodiment, the semiconductor substrate 37 may be a silicon-made FZ substrate that is formed by an FZ (Floating Zone) method. The semiconductor chip 16 is formed as a whole in a layered shape and, therefore, may be referred to as a semiconductor layer.

The semiconductor chip 16 includes an n⁻ type drift region 38. The drift region 38 is, specifically, formed in an entire area of the semiconductor chip 16 in the first direction X and in the second direction Y. With reference to FIG. 3, the drift region 38 is formed not only in the element forming region 20 but also in the outer region 21 and the scribe region 22. The drift region 38 is formed at a surface layer portion of the first principal surface 17 of the semiconductor chip 16 in the normal direction Z (thickness direction of the semiconductor chip 16). An n-type impurity concentration of the drift region 38 may be not less than 1.0×10¹³ cm⁻³ and not more than 1.0×10¹⁵ cm⁻³.

The semiconductor device 1 includes a collector terminal electrode 13 as an example of a rear surface electrode that is formed on the second principal surface 18 of the semiconductor chip 16. The collector terminal electrode 13 is electrically connected to the second principal surface 18. The collector terminal electrode 13 forms an ohmic contact with the second principal surface 18. The collector terminal electrode 13 may include at least one among a Ti layer, an Ni layer, an Au layer, an Ag layer and an Al layer. The collector terminal electrode 13 may have a single layered structure that includes a Ti layer, an Ni layer, an Au layer, an Ag layer or an Al layer. The collector terminal electrode 13 may have a laminated structure in which at least two among a Ti layer, an Ni layer, an Au layer, an Ag layer and an Al layer are laminated in an arbitrary mode.

The semiconductor device 1 includes an n-type buffer layer 39 that is formed at a surface layer portion of the second principal surface 18 of the semiconductor chip 16. The buffer layer 39 may be formed in an entire area of the surface layer portion of the second principal surface 18. An n-type impurity concentration of the buffer layer 39 is higher than the n-type impurity concentration of the drift region 38. The n-type impurity concentration of the buffer layer 39 may be not less than 1.0×10¹⁵ cm⁻³ and not more than 1.0×10¹⁷ cm⁻³. A thickness of the buffer layer 39 may be not less than 0.5 μm and not more than 30 μm. The thickness of the buffer layer 39 may be not less than 0.5 μm and not more than 5 μm, not less than 5 μm and not more than 10 μm, not less than 10 μm and not more than 15 μm, not less than 15 μm and not more than 20 μm, not less than 20 μm and not more than 25 μm, or not less than 25 μm and not more than 30 μm.

The element forming region 20 includes a p-type collector region 40 that is formed at the surface layer portion of the second principal surface 18 of the semiconductor chip 16. The collector region 40 is exposed from the second principal surface 18. The collector region 40 may be formed in an entire area of the semiconductor chip 16 at the surface layer portion of the second principal surface 18. With reference to FIG. 3, the collector region 40 is formed not only in the element forming region 20 but also in the outer region 21 and the scribe region 22. The collector region 40 is formed not only in an opposition region that opposes a body region 46 to be described later but also in a non-opposition region that does not oppose the body region 46. A p-type impurity concentration of the collector region 40 may be not less than 1.0×10¹⁵ cm⁻³ and not more than 1.0×10¹⁸ cm⁻³. The collector region 40 forms an ohmic contact with the collector terminal electrode 13.

With reference to FIG. 3 and FIG. 4B, the element forming region 20 includes an FET structure 41 that is formed in the first principal surface 17 of the semiconductor chip 16. In this preferred embodiment, the element forming region 20 includes a trench gate type FET structure 41. Specifically, the FET structure 41 includes a trench gate structure 42 that is formed in the first principal surface 17.

The plurality of trench gate structures 42 are formed in the element forming region 20 at an interval along the first direction X. A distance between two trench gate structures 42 that are adjacent to each other in the first direction X may be not less than 1 μm and not more than 8 μm. The distance between the two trench gate structures 42 may be not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, or not less than 7 μm and not more than 8 μm.

Although not shown, the plurality of trench gate structures 42 may be formed as a band extending along the second direction Y in a plan view. The plurality of trench gate structures 42 may be formed as a whole in a stripe pattern. The plurality of trench gate structures 42 each have one end portion at one side in the second direction Y and the other end portion at the other side in the second direction Y. The trench gate structures 42 may be formed in a lattice pattern in a plan view.

With reference to FIG. 4B, each of the trench gate structures 42 includes a gate trench 43, a gate insulating layer 44 and a gate electrode layer 45. The gate trench 43 is formed in the first principal surface 17. The gate trench 43 includes a side wall and a bottom wall. The side wall of the gate trench 43 may be formed perpendicular with respect to the first principal surface 17.

The side wall of the gate trench 43 may be inclined downwardly from the first principal surface 17 to the bottom wall. The gate trench 43 may be formed in a tapered shape in which an opening area at the opening side is larger than a bottom area. The bottom wall of the gate trench 43 may be formed parallel to the first principal surface 17. The bottom wall of the gate trench 43 may be formed in a curved shape toward the second principal surface 18. The gate trench 43 includes a bottom wall edge portion. The bottom wall edge portion connects the side wall and the bottom wall of the gate trench 43. The bottom wall edge portion may be formed in a curved shape toward the second principal surface 18.

A depth of the gate trench 43 may be not less than 2 μm and not more than 10 μm. The depth of the gate trench 43 may be not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 8 μm and not more than 9 μm, or not less than 9 μm and not more than 10 μm. The depth of the gate trench 43 may be defined as a distance between a depth position of the deepest portion of the bottom wall of the gate trench 43 and the first principal surface 17.

A width of the gate trench 43 may be not less than 0.5 μm and not more than 3 μm. The width of the gate trench 43 is a width of the gate trench 43 in the first direction X. The width of the gate trench 43 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm.

The gate insulating layer 44 is formed as a film along an inner wall of the gate trench 43. The gate insulating layer 44 demarcates a recessed space inside the gate trench 43. In this preferred embodiment, the gate insulating layer 44 includes a silicon oxide film. The gate insulating layer 44 may include a silicon nitride film in place of, or in addition to the silicon oxide film.

The gate electrode layer 45 is embedded in the gate trench 43 across the gate insulating layer 44. Specifically, the gate electrode layer 45 is embedded in a recessed space that is demarcated by the gate insulating layer 44 in the gate trench 43. The gate electrode layer 45 is controlled by a gate signal. The gate electrode layer 45 may contain a conductive polysilicon.

The gate electrode layer 45 is formed as a wall extending along the normal direction Z in a cross sectional view. The gate electrode layer 45 has an upper end portion that is positioned at the opening side of the gate trench 43. The upper end portion of the gate electrode layer 45 is positioned at the bottom wall side of the gate trench 43 with respect to the first principal surface 17.

With reference to FIG. 3 and FIG. 4B, the FET structure 41 includes a p-type body region 46 that is formed at the surface layer portion of the first principal surface 17 of the semiconductor chip 16. A p-type impurity concentration of the body region 46 may be not less than 1.0×10¹⁷ cm⁻³ and not more than 1.0×10¹⁸ cm⁻³. The body regions 46 are each formed at the both sides of the trench gate structure 42. The body region 46 is formed as a band extending along the trench gate structure 42 in a plan view. The body region 46 is exposed from the side wall of the gate trench 43. A bottom portion of the body region 46 is formed in a region between the first principal surface 17 and the bottom wall of the gate trench 43 with respect to the normal direction Z.

With reference to FIG. 4B, the FET structure 41 includes an n⁺ type emitter region 47 that is formed at a surface layer portion of the body region 46. An n-type impurity concentration of the emitter region 47 is higher than the n-type impurity concentration of the drift region 38. The n-type impurity concentration of the emitter region 47 may be not less than 1.0×10¹⁹ cm⁻³ and not more than 1.0×10²⁰ cm⁻³.

In this preferred embodiment, the FET structure 41 includes the plurality of emitter regions 47 that are formed at both sides of the trench gate structure 42. The emitter region 47 is formed as a band extending along the trench gate structure 42 in a plan view. The emitter region 47 is exposed from the first principal surface 17 and the side wall of the gate trench 43. A bottom portion of the emitter region 47 is formed in a region between the upper end portion of the gate electrode layer 45 and the bottom portion of the body region 46 with respect to the normal direction Z.

With reference to FIG. 4, in this preferred embodiment, the FET structure 41 includes an n⁺ type carrier storage region 48 that is formed in a region of the semiconductor chip 16 at the second principal surface 18 side with respect to the body region 46. An n-type impurity concentration of the carrier storage region 48 is higher than the n-type impurity concentration of the drift region 38. The n-type impurity concentration of the carrier storage region 48 may be not less than 1.0×10¹⁵ cm⁻³ and not more than 1.0×10¹⁷ cm⁻³.

In this preferred embodiment, the FET structure 41 includes the plurality of carrier storage regions 48 that are formed at both sides of the trench gate structure 42. The carrier storage region 48 is formed as a band extending along the trench gate structure 42 in a plan view. The carrier storage region 48 is exposed from the side wall of the gate trench 43. A bottom portion of the carrier storage region 48 is formed in a region between the bottom portion of the body region 46 and the bottom wall of the gate trench 43 with respect to the normal direction Z.

The carrier storage region 48 suppresses carriers (holes) supplied to the semiconductor chip 16 from being returned (discharged) to the body region 46. Thereby, the holes are accumulated in a region directly under the FET structure 41 in the semiconductor chip 16. As a result, a decrease in on-resistance and a decrease in on-voltage are attained.

With reference to FIG. 3 and FIG. 4B, the FET structure 41 includes a contact trench 49 that is formed in the first principal surface 17 of the semiconductor chip 16. In this preferred embodiment, the FET structure 41 includes the plurality of contact trenches 49 that are formed at both sides of the trench gate structure 42. The contact trench 49 exposes the emitter region 47. In this preferred embodiment, the contact trench 49 penetrates through the emitter region 47. The contact trench 49 is formed at an interval from the trench gate structure 42 in the first direction X. The contact trench 49 extends as a band along the trench gate structure 42 in a plan view.

With reference to FIG. 4B, the FET structure 41 includes a p⁺ type contact region 50 that is formed in a region along a bottom wall of the contact trench 49 in the body region 46. A p-type impurity concentration of the contact region 50 is higher than the p-type impurity concentration of the body region 46. The p-type impurity concentration of the contact region 50 may be not less than 1.0×10¹⁹ cm⁻³ and not more than 1.0×10²⁰ cm⁻³. The contact region 50 is exposed from the bottom wall of the contact trench 49. The contact region 50 extends as a band along the contact trench 49 in a plan view. A bottom portion of the contact region 50 is formed in a region between the bottom wall of the contact trench 49 and the bottom portion of the body region 46 with respect to the normal direction Z.

As described so far, in the FET structure 41, the gate electrode layer 45 opposes the body region 46 and the emitter region 47 across the gate insulating layer 44. In this preferred embodiment, the gate electrode layer 45 also opposes the carrier storage region 48 across the gate insulating layer 44. A channel of the IGBT is formed in a region between the emitter region 47 and the drift region 38 (carrier storage region 48) in the body region 46. On/off of the channel is controlled by a gate signal.

With reference to FIG. 3 and FIG. 4B, the element forming region 20 includes an emitter trench structure 51 in the first principal surface 17 of the semiconductor chip 16. The emitter trench structure 51 is formed in a region adjacent to the trench gate structure 42 at the surface layer portion of the first principal surface 17. The emitter trench structure 51 is formed as a band extending along the second direction Y in a plan view. The plurality of emitter trench structures 51 may be formed in a stripe pattern as a whole. The emitter trench structure 51 may be in a band shape parallel to the trench gate structure 42.

In the element forming region 20, the trench gate structure 42 and the emitter trench structure 51 are arrayed alternately at an interval along the first direction X. The trench gate structure 42 and the emitter trench structure 51 may be arrayed alternately, with an equal interval kept. A distance (pitch) between two of the trench gate structure 42 and the emitter trench structure 51 that are adjacent to each other in the first direction X may be, for example, not less than 1.0 μm and not more than 3.5 μm. Also, with reference to FIG. 5, the trench gate structure 42 may have a portion that extends longer than the emitter trench structure 51 in the second direction Y and extends in the first direction X in a region away from an end portion of the emitter trench structure 51.

With reference to FIG. 4B, the emitter trench structure 51 includes an emitter trench 52, an emitter insulating layer 53 and an emitter potential electrode layer 54. The emitter trench 52 is formed in the first principal surface 17 of the semiconductor chip 16. The emitter trench 52 includes a side wall and a bottom wall. The side wall of the emitter trench 52 may be formed perpendicular to the first principal surface 17.

The side wall of the emitter trench 52 may be inclined downwardly from the first principal surface 17 toward the bottom wall. The emitter trench 52 may be formed in a tapered shape in which an opening area at the opening side is larger than a bottom area. The emitter region 47, the body region 46 and the carrier storage region 48 are exposed from a side wall (outer side wall) that faces the trench gate structure 42 in the emitter trench 52. The bottom wall of the emitter trench 52 may be formed parallel to the first principal surface 17. The bottom wall of the emitter trench 52 may be formed in a curved shape toward the second principal surface 18. The emitter trench 52 includes a bottom wall edge portion. The bottom wall edge portion connects the side walls and the bottom wall of the emitter trench 52. The bottom wall edge portion may be formed in a curved shape toward the second principal surface 18 of the semiconductor chip 16.

A depth of the emitter trench 52 may be not less than 2 μm and not more than 10 μm. The depth of the emitter trench 52 may be not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 8 μm and not more than 9 μm, or not less than 9 μm and not more than 10 μm. The depth of the emitter trench 52 may be equal to the depth of the gate trench 43.

A width of the emitter trench 52 may be not less than 0.5 μm and not more than 3 μm. The width of the emitter trench 52 is a width of the emitter trench 52 in the first direction X. The width of the emitter trench 52 may be not less than 0.5 μm and not more than 1 μm, not less than 1 μm and not more than 1.5 μm, not less than 1.5 μm and not more than 2 μm, not less than 2 μm and not more than 2.5 μm, or not less than 2.5 μm and not more than 3 μm. The width of the emitter trench 52 may be equal to the width of the gate trench 43.

The emitter insulating layer 53 is formed as a film along an inner wall of the emitter trench 52. The emitter insulating layer 53 demarcates a recessed space inside the emitter trench 52. In this preferred embodiment, the emitter insulating layer 53 includes a silicon oxide film. The emitter insulating layer 53 may include a silicon nitride film in place of, or in addition to the silicon oxide film.

The emitter potential electrode layer 54 is embedded in the emitter trench 52 across the emitter insulating layer 53. Specifically, the emitter potential electrode layer 54 is embedded in a recessed space that is demarcated by the emitter insulating layer 53 in the emitter trench 52. The emitter potential electrode layer 54 may contain a conductive polysilicon. The emitter potential electrode layer 54 is controlled by an emitter signal.

The emitter potential electrode layer 54 is formed as a wall extending along the normal direction Z in a cross sectional view. The emitter potential electrode layer 54 has an upper end portion that is positioned at the opening side of the emitter trench 52. The upper end portion of the emitter potential electrode layer 54 is positioned at the bottom wall side of the emitter trench 52 with respect to the first principal surface 17.

With reference to FIG. 4B and FIG. 5, a first front surface insulating film 55 that covers the first principal surface 17 is formed in the first principal surface 17 of the semiconductor chip 16 outside the gate trench 43 and the emitter trench 52. The gate insulating layer 44 and the emitter insulating layer 53 are continuous to the first front surface insulating film 55 outside the gate trench 43 and the emitter trench 52. The first front surface insulating film 55 is integrally formed with the gate insulating layer 44 and the emitter insulating layer 53 by use of the same insulating material as the gate insulating layer 44 and the emitter insulating layer 53.

With reference to FIG. 5, a gate lead-out electrode layer 56 and an emitter lead-out electrode layer 57 are formed on the first front surface insulating film 55.

The gate lead-out electrode layer 56 is an electrode layer that is led out to the outside of the gate trench 43 from the upper end portion of the gate electrode layer 45. The gate lead-out electrode layer 56 is integrally formed with the gate electrode layer 45 by use of the same conductive material as the gate electrode layer 45. It is noted that, in FIG. 3, the gate lead-out electrode layer 56 is in contact with the first principal surface 17. However, in principle, a space between the semiconductor chip 16 and the gate lead-out electrode layer 56 is insulated by the first front surface insulating film 55. With reference to FIG. 3, the gate lead-out electrode layer 56 is led out to a region directly under the gate finger 28 (gate terminal electrode 12). The gate lead-out electrode layer 56 is electrically connected to the gate finger 28. Thereby, the trench gate structure 42 is electrically connected to the gate terminal electrode 12.

The emitter lead-out electrode layer 57 is an electrode layer that is led out outside the emitter trench 52 from the upper end portion of the emitter potential electrode layer 54. The emitter lead-out electrode layer 57 is integrally formed with the emitter potential electrode layer 54 by use of the same conductive material as the emitter potential electrode layer 54. With reference to FIG. 5, the emitter lead-out electrode layer 57 is led out to a region directly under the emitter terminal electrode 11. The emitter lead-out electrode layer 57 is electrically connected to the emitter terminal electrode 11. A space between the emitter lead-out electrode layer 57 and the emitter terminal electrode 11 may be connected by a laminated structure of a barrier layer 105 (for example, titanium-based metal) and a contact plug 106 (for example, tungsten). Thereby, the emitter trench structure 51 is electrically connected to the emitter terminal electrode 11.

With reference to FIG. 4B and FIG. 5, a second front surface insulating film 58 is formed on the first principal surface 17 of the semiconductor chip 16. The second front surface insulating film 58 is formed in the front surfaces of the gate electrode layer 45, the gate lead-out electrode layer 56, the emitter potential electrode layer 54 and the emitter lead-out electrode layer 57 and covers the gate electrode layer 45, the gate lead-out electrode layer 56, the emitter potential electrode layer 54 and the emitter lead-out electrode layer 57. The second front surface insulating film 58 may be an insulating film that is in contact with the gate electrode layer 45, the gate lead-out electrode layer 56, the emitter potential electrode layer 54 and the emitter lead-out electrode layer 57. In this preferred embodiment, the second front surface insulating film 58 includes a silicon oxide film. The second front surface insulating film 58 may include a silicon nitride film in place of, or in addition to the silicon oxide film.

With reference to FIG. 3, a termination region 59 as an example of the withstand-voltage holding structure is formed at the surface layer portion of the first principal surface 17 of the semiconductor chip 16 in the outer region 21. The termination region 59 is a p-type impurity region that is formed by introducing a p-type impurity into the n⁻ type drift region 38. The termination region 59 is formed in an endless shape that surrounds the element forming region 20.

The termination region 59 includes a RESURF layer 60 and a field limit region 61.

The RESURF layer 60 relaxes an electric field in the outer region 21. The RESURF layer 60 may be a region high in concentration and low in resistance that has a p-type impurity concentration higher than the p-type impurity concentration of the body region 46. In this preferred embodiment, the RESURF layer 60 is formed in an endless shape (quadrilateral annular shape in a plan view) that surrounds the element forming region 20. A bottom portion of the RESURF layer 60 is formed at a position closer to the second principal surface 18 of the semiconductor chip 16 than the bottom portion of the body region 46 with respect to a thickness direction of the semiconductor chip 16. The bottom portion of the RESURF layer 60 is formed at a position closer to the second principal surface 18 of the semiconductor chip 16 than the bottom portions of the trench gate structure 42 and the emitter trench structure 51 with respect to the thickness direction of the semiconductor chip 16.

The RESURF layer 60 overlaps with the bottom portions of the trench gate structure 42 and the emitter trench structure 51. In FIG. 3, an end of the stripe of the trench gate structure 42 and the emitter trench structure 51 that are arranged in the first direction X is the emitter trench structure 51 and, therefore, the RESURF layer 60 overlaps with an entirety of the bottom portion of the emitter trench structure 51 and a part of the bottom portion of the trench gate structure 42. On the other hand, although not shown, where the end of the stripe is the trench gate structure 42, the RESURF layer 60 may overlap with an entirety of the bottom portion of the trench gate structure 42 and a part of the bottom portion of the emitter trench structure 51.

The bottom portion of the RESURF layer 60 is formed at an interval at the first principal surface 17 side of the semiconductor chip 16 from the collector region 40. The RESURF layer 60 opposes the collector region 40 across a certain region of the drift region 38. The RESURF layer 60 opposes the emitter terminal electrode 11 and the gate terminal electrode 12 (gate finger 28) across the first front surface insulating film 55 (omitted in FIG. 3). The RESURF layer 60 opposes the gate lead-out electrode layer 56 across the first front surface insulating film 55 (omitted in FIG. 3).

The field limit region 61 relaxes an electric field in the outer region 21. The field limit region 61 has a p-type impurity concentration that is substantially the same as the p-type impurity concentration of the RESURF layer 60. The field limit region 61 may have a depth substantially the same as the depth of the RESURF layer 60. The field limit region 61 is formed along the RESURF layer 60 in the outer region 21. In this preferred embodiment, the field limit region 61 is formed in an endless shape (quadrilateral annular shape in a plan view) that surrounds the RESURF layer 60. Thereby, the field limit region 61 is formed as an FLR (Field Limiting Ring) region.

In this preferred embodiment, the field limit region 61 includes the plurality of (in this preferred embodiment, four) field limit regions 61 that are formed at an interval from the element forming region 20 toward the scribe region 22. At least, the one field limit region 61 may be formed. Therefore, four or more of the field limit regions 61 may be formed.

With reference to FIG. 4A, a field insulating layer 62 is formed in the first principal surface 17 of the semiconductor chip 16 in the outer region 21. The field insulating layer 62 is selectively formed in a region in which the n-type impurity region (drift region 38 in this preferred embodiment) is exposed, with no termination region 59 formed in the first principal surface 17. More specifically, it is formed so as to cover the drift region 38 in a region between the termination regions 59 that are adjacent to each other. In FIG. 4A, there is shown the field insulating layer 62 on a region held between the field limit regions 61 that are adjacent to each other. However, the field insulating layer 62 may also be formed in a region between the field limit region 61 and the RESURF layer 60 and in a region between the field limit region 61 and a channel stop region 65 to be described later. In other words, the field insulating layer 62 has a plurality of openings 63 which selectively exposes the first principal surface 17, and the termination region 59 may be exposed from the openings 63.

In this preferred embodiment, the field insulating layer 62 may be a LOCOS (Local oxidation of silicon) oxide film. Also, a thickness TF of the field insulating layer 62 may be, for example, not less than 5000 Å and not more than 20000 Å. Also, a third front surface insulating film 64 is formed in the first principal surface 17 that is exposed from the opening 63 of the field insulating layer 62. In this preferred embodiment, the third front surface insulating film 64 includes a silicon oxide film. The third front surface insulating film 64 may include a silicon nitride film in place of, or in addition to the silicon oxide film. The third front surface insulating film 64 is formed in an entirety of the opening 63 and covers a front surface of the termination region 59.

With reference to FIG. 3, the n⁺ type channel stop region 65 is formed at the surface layer portion of the first principal surface 17 of the semiconductor chip 16 in the scribe region 22. The channel stop region 65 is a region high in concentration and low in resistance that has an n-type impurity concentration higher than the n-type impurity concentration of the n⁻ type drift region 38. The channel stop region 65 suppresses a depletion layer from expanding from a pn junction portion that is formed in an inner region of the semiconductor chip 16.

The channel stop region 65 is formed along the field limit region 61. The channel stop region 65 is formed in an endless shape (quadrilateral annular shape in a plan view) that surrounds the field limit region 61. The channel stop region 65 may be formed so as to cross a boundary portion between the outer region 21 and the scribe region 22.

With reference to FIG. 3, an interlayer insulating layer 66 is formed on the first principal surface 17 of the semiconductor chip 16. The interlayer insulating layer 66 covers the element forming region 20, the outer region 21 and the scribe region 22. The interlayer insulating layer 66 is different in thickness for each region of the semiconductor chip 16 that is covered by the interlayer insulating layer 66 and different in thickness among the plurality of regions. In this preferred embodiment, a thickness TA of an element covering portion 67 of the interlayer insulating layer 66 that covers the element forming region 20 is thinner than a thickness TC of an outer covering portion 68 of the interlayer insulating layer 66 that covers the outer region 21. For example, the thickness TA may be not less than 3000 Å and not more than 20000 Å, and the thickness TC may be not less than 4000 Å and not more than 30000 Å. It is noted that the thickness TA and the thickness TC may be both thicker than the thickness TF (refer to FIG. 4A) of the field insulating layer 62. A step 70 is formed at a boundary portion 69 between the element forming region 20 and the outer region 21 due to a difference between the thickness TA and the thickness TC in a front surface of the interlayer insulating layer 66. It is noted that the field insulating layer 62 and the interlayer insulating layer 66 may be collectively and simply referred to as an interlayer insulating layer.

With reference to FIG. 3, a first contact hole 71, a second contact hole 72 and a third contact hole 73 for the emitter terminal electrode 11 are formed in the interlayer insulating layer 66. The first contact hole 71 is in communication with the contact trench 49. The first contact hole 71 may be referred to as an emitter contact hole.

The second contact hole 72 is formed in a mode of penetrating through the interlayer insulating layer 66 and digging into a part of the first principal surface 17 (RESURF layer 60) of the semiconductor chip 16. The second contact hole 72 may be formed so as to extend along a stripe of the FET structure 41. A p⁺ type contact region 77 is formed at a bottom portion of the second contact hole 72. The contact region 77 may be a region high in concentration in which the p-type impurity concentration is higher than those of the other regions in the RESURF layer 60. The second contact hole 72 may be referred to as a first outer emitter contact hole.

The third contact hole 73 is formed in a mode of penetrating through the interlayer insulating layer 66 and digging into a part of the first principal surface 17 (RESURF layer 60) of the semiconductor chip 16. The third contact hole 73 may be formed so as to extend along the emitter routing portion 34. A p⁺ type contact region 78 is formed at a bottom portion of the third contact hole 73. The contact region 78 may be a region high in concentration in which the p-type impurity concentration is higher than those of the other regions (excluding the contact region 77) in the RESURF layer 60. The contact region 78 may have substantially the same impurity concentration as the contact region 77. The third contact hole 73 may be referred to as a second outer emitter contact hole.

A fourth contact hole 74 for the gate terminal electrode 12 is formed in the interlayer insulating layer 66. The gate lead-out electrode layer 56 is exposed from the fourth contact hole 74. The fourth contact hole 74 may be formed so as to extend along the gate finger 28. The fourth contact hole 74 may be referred to as a gate contact hole.

A fifth contact hole 75 for the field plate electrode 24 is formed in the interlayer insulating layer 66. In this preferred embodiment, the plurality of fifth contact holes 75 are formed in a one-to-one correspondence relationship with the plurality of field limit regions 61. The fifth contact holes 75 are each formed in a mode of penetrating through the interlayer insulating layer 66 and digging into a part of the first principal surface 17 (field limit region 61) of the semiconductor chip 16. The fifth contact holes 75 are each formed along the first to fourth side surfaces 19A to 19D of the semiconductor chip 16 and may be formed in an endless shape (quadrilateral annular shape in a plan view) that surrounds the element forming region 20. The field limit region 61 is exposed from a bottom portion of each of the fifth contact holes 75. The fifth contact hole 75 may be referred to as a field contact hole.

A sixth contact hole 76 for the equipotential electrode 25 is formed in the interlayer insulating layer 66. The sixth contact hole 76 is formed in a mode of penetrating through the interlayer insulating layer 66 and digging into a part of the first principal surface 17 (channel stop region 65) of the semiconductor chip 16. The sixth contact hole 76 further extends up to the first to fourth side surfaces 19A to 19D (the fourth side surface 19D is shown in FIG. 3) of the semiconductor chip 16 and is opened in the first to fourth side surfaces 19A to 19D. Also, the sixth contact hole 76 is formed along the first to fourth side surfaces 19A to 19D of the semiconductor chip 16 and may be formed in an endless shape (quadrilateral annular shape in a plan view) that surrounds the outer region 21 and the element forming region 20. In view of the fact that the sixth contact hole 76 is a step portion that is formed at a peripheral edge portion of the semiconductor chip 16, it may be referred to as a peripheral edge step portion of the semiconductor chip 16. A p⁺ type contact region 79 is formed in a region along the bottom portion of the sixth contact hole 76 in the semiconductor chip 16. The contact region 79 may have substantially the same impurity concentration as the contact region 77 and the contact region 78.

On the interlayer insulating layer 66, the aforementioned front surface electrode 23 is formed. The front surface electrode 23 is a conductive film that is formed in the outermost front surface of the semiconductor chip 16 and may be referred to as a front surface electrode film or a front surface conductive film. As described above, the front surface electrode 23 includes the emitter terminal electrode 11, the gate terminal electrode 12, the field plate electrode 24 and the equipotential electrode 25. The emitter terminal electrode 11 is electrically connected to the FET structure 41 via the first contact hole 71 and electrically connected to the RESURF layer 60 via the second contact hole 72 and the third contact hole 73. The gate terminal electrode 12 is electrically connected to the gate lead-out electrode layer 56 via the fourth contact hole 74. The field plate electrode 24 is electrically connected to the field limit region 61 via the fifth contact hole 75. The equipotential electrode 25 is electrically connected to the channel stop region 65 via the sixth contact hole 76.

With reference to FIG. 3, in this preferred embodiment, there is a difference in height from the first principal surface 17 of the semiconductor chip 16 to the front surface thereof between a first electrode portion of the surface electrode 23 on the element forming region 20 and a second electrode portion thereof on the outer region 21 and the scribe region 22. In this preferred embodiment, a height of the front surface of the second electrode portion, H2, is higher than a height of the front surface of the first electrode portion, H1. As a concept, for example, the gate finger 28, the emitter routing portion 34, the field plate electrode 24, the equipotential electrode 25, etc., are included in the second electrode portion. The emitter pad 33 is included as a concept in the first electrode portion. The height of the front surface, H1 and the height of the front surface, H2 may be, for example, as shown in FIG. 3, a distance between the first principal surface 17 of the semiconductor chip 16 to a front surface of each portion of the front surface electrode 23. Thereby, a difference in height G is formed in the front surface electrode 23 across the boundary portion 69. The difference in height G may be, for example, not less than 3000 Å and not more than 20000 Å.

A protective layer 80 is formed on the interlayer insulating layer 66. The protective layer 80 is an insulating layer that covers the outermost front surface of the semiconductor chip 16 and may be referred to as a front surface protective layer or an organic resin layer. The protective layer 80 may be formed, for example, of a polyimide resin or a PBO (Polybenzoxazole) resin. A thickness of the protective layer 80 is, for example, not less than 3 μm and not more than 15 μm. The protective layer 80 selectively covers the front surface electrode 23. More specifically, the protective layer 80 has an opening 81 that exposes the emitter pad 33 in the element forming region 20 and it covers the front surface electrode 23 in the outer region 21.

### [Withstand-Voltage Decrease Preventive Structure of Element Chip 10 (First Mode)]

Next, with reference to FIG. 6 and FIG. 7 in addition to FIG. 3, FIG. 4A and FIG. 4B, a description will be given of a withstand-voltage decrease preventive structure of the element chip 10.

First, with reference to FIG. 3, in this preferred embodiment, a space 82 is provided between individual portions of the front surface electrode 23 in the outer region 21. The space 82 may include, sequentially from the right to the left on the paper in FIG. 3, for example, a space 82 that is held between the gate finger 28 and the emitter routing portion 34 adjacent thereto, a space 82 held between the emitter routing portion 34 and the field plate electrode 24 adjacent thereto, a space 82 held between the mutually adjacent field plate electrodes 24 (three in FIG. 3), and a space 82 held between the field plate electrode 24 and the equipotential electrode 25 adjacent thereto.

Where the protective layer 80 is an organic resin layer, the organic resin layer has a sufficient resistance against an external mechanical stress such as a scratch, but it is difficult to say that it has a sufficient resistance against intrusion of moisture (OH⁻, H⁺ etc.) from the outside. Therefore, there is a case that moisture that has passed through the protective layer 80 and the space 82 enters into the interlayer insulating layer 66 and causes polarization, by which a withstand-voltage holding structure portion such as the termination region 59 may lose the balance of an electric field, resulting in a change in withstand voltage. Thus, in this preferred embodiment, as shown in FIG. 4A, FIG. 6 and FIG. 7, a sealing conductive layer 83 that is insulated from the semiconductor chip 16 is provided in the interlayer insulating layer 66 and covers a part of the interlayer insulating layer 66, thereby preventing an external intrusion of moisture (OH⁻, H⁺ etc.). In view of the fact that the sealing conductive layer 83 covers a part of the interlayer insulating layer 66, it may be referred to as a covering conductive layer.

Next, a specific description will be given of the withstand-voltage decrease preventive structure including the sealing conductive layer 83 by referring to FIG. 4A, FIG. 4B, FIG. 6 and FIG. 7. It is noted that, although FIG. 4A shows the sealing conductive layer 83 that opposes the space 82 held between the mutually adjacent field plate electrodes 24, a similar sealing conductive layer 83 can be arranged at the other space 82 as well.

First, with reference to FIG. 4A, the field plate electrode 24 includes a contact portion 84 and a surface layer portion 85.

The contact portion 84 is embedded in the interlayer insulating layer 66 and connected to the field limit region 61. In this preferred embodiment, the interlayer insulating layer 66 has a laminated structure of a first layer 86 and a second layer 87 on the first layer 86. The contact portion 84 reaches the field limit region 61 via the fifth contact hole 75 that successively penetrates through the first layer 86 and the second layer 87. A boundary portion 88 between the first layer 86 and the second layer 87 of the interlayer insulating layer 66 is clearly shown in FIG. 4A. However, where the first layer 86 and the second layer 87 are formed of the same material, the boundary portion 88 may not be confirmed. In this case, based on a height from the first principal surface 17, a portion corresponding to the first layer 86 may be referred to as a first portion, and a portion corresponding to the second layer 87 may be referred to as a second portion.

The first layer 86 and the second layer 87 respectively have a first thickness T1 and a second thickness T2 which are uniform along the first principal surface 17. The first thickness T1 of the first layer 86 may be thicker than the second thickness T2 of the second layer 87. For example, the first thickness T1 may be not less than 3000 Å and not more than 20000 Å, and second thickness T2 may be not less than 1000 Å and not more than 10000 Å. The thickness TC of the outer covering portion 68 of the interlayer insulating layer 66 shown in FIG. 3 may be a total thickness of the first thickness T1 and the second thickness T2. It is noted that, in FIG. 4A, the structure of the semiconductor chip 16 is deformed and a part of the second layer 87 is shown so as to be thicker. Therefore, apparently, the thickness TC is thicker than a total thickness of the first thickness T1 and the second thickness T2.

On the other hand, as described above, the thickness TA of the element covering portion 67 of the interlayer insulating layer 66 is thinner than the thickness TC of the outer covering portion 68 of the interlayer insulating layer 66 that covers the outer region 21. The thickness TA may be substantially the same as the first thickness T1. Therefore, the thickness TA may be, for example, not less than 3000 Å and not more than 20000 Å. Due to the difference between the thickness TA and the thickness TC, the difference in height G (refer to FIG. 3) is formed in the front surface electrode 23.

For example, on the element covering portion 67 that is relatively thin, the front surface height H1 of the front surface electrode 23 is not less than 10000 Å and not more than 75000 Å. On the other hand, on the outer covering portion 68 that is relatively thick as compared with the element covering portion 67, the front surface height H2 of the front surface electrode 23 may be, for example, not less than 15000 Å and not more than 95000 Å. For example, a difference in height G that corresponds to the second thickness T2 of the second layer 87 may be formed between the front surface height H1 and the front surface height H2.

The fifth contact hole 75 may include a lower contact hole 89 and an upper contact hole 90. The lower contact hole 89 is formed in the first layer 86, and the upper contact hole 90 is formed in the second layer 87. The lower contact hole 89 may have a width narrower than the upper contact hole 90. The lower contact hole 89 is formed in a mode of penetrating through the first layer 86 of the interlayer insulating layer 66 and digging into a part of the first principal surface 17 (field limit region 61) of the semiconductor chip 16. A p⁺ type contact region 91 is formed at a bottom portion of the lower contact hole 89. The contact region 91 may be a high concentration region in which a p-type impurity concentration is higher than those of the other regions in the field limit region 61.

The contact portion 84 of the field plate electrode 24 may include a first embedded portion 92 that is embedded in the lower contact hole 89 and a second embedded portion 93 that is embedded in the upper contact hole 90.

In this preferred embodiment, the first embedded portion 92 has a laminated structure that includes a barrier layer 94 and a contact plug 95. The first embedded portion 92 may be referred to as a field plug electrode. The barrier layer 94 is formed as a film along an inner wall of the lower contact hole 89 so as to be in contact with the interlayer insulating layer 66. The barrier layer 94 demarcates a recessed space inside the lower contact hole 89. The barrier layer 94 may have a single layered structure that includes a titanium-based metal, more specifically, a titanium layer or a titanium nitride layer. The barrier layer 94 may have a laminated structure that includes a titanium layer and a titanium nitride layer. In this case, the titanium nitride layer may be laminated on the titanium layer. The barrier layer 94 is further led out to a front surface of the first layer 86 from the lower contact hole 89 and selectively formed in the front surface of the first layer 86.

The contact plug 95 is embedded in the lower contact hole 89 across the barrier layer 94. Specifically, the contact plug 95 is embedded in a recessed space that is demarcated by the barrier layer 94 in the lower contact hole 89. The contact plug 95 may contain tungsten.

The second embedded portion 93 is formed of a conductive material that is different from the contact plug 95. In this preferred embodiment, the second embedded portion 93 is formed of an aluminum-based metal. More specifically, the second embedded portion 93 may contain at least one among aluminum, copper, an aluminum-silicon-copper alloy, an aluminum-silicon alloy and an aluminum-copper alloy.

Similarly, with reference to FIG. 4B, an emitter plug electrode 96 is embedded in the first contact hole 71. In this preferred embodiment, the emitter plug electrode 96 has a laminated structure that includes a barrier layer 97 and a contact plug 98. The barrier layer 97 is formed as a film along an inner wall of the first contact hole 71 so as to be in contact with the interlayer insulating layer 66. The barrier layer 97 demarcates a recessed space inside the first contact hole 71. The barrier layer 97 may have a single layered structure that includes a titanium-based metal, more specifically, a titanium layer or a titanium nitride layer. The barrier layer 97 may have a laminated structure that includes a titanium layer and a titanium nitride layer. In this case, the titanium nitride layer may be laminated on the titanium layer. The barrier layer 97 is further led out to the front surface of the interlayer insulating layer 66 from the first contact hole 71 and selectively formed at the front surface of the interlayer insulating layer 66.

The contact plug 98 is embedded in the first contact hole 71 across the barrier layer 97. Specifically, the contact plug 98 is embedded in a recessed space that is demarcated by the barrier layer 97 in the first contact hole 71. The contact plug 98 may contain tungsten.

The emitter terminal electrode 11 is formed of a conductive material that is different from the contact plug 98. In this preferred embodiment, the emitter terminal electrode 11 is formed of an aluminum-based metal. More specifically, the emitter terminal electrode 11 may contain at least one among aluminum, copper, an aluminum-silicon-copper alloy, an aluminum-silicon alloy, and an aluminum-copper alloy. It is noted that the gate terminal electrode 12 and the equipotential electrode 25 that are other portions of the front surface electrode 23 may also be formed of the same conductive material as the emitter terminal electrode 11. As described so far, where the front surface electrode 23 is formed of a metal material, the front surface electrode 23 may be referred to as a front surface metal.

The surface layer portion 85 is formed as a lead-out portion that is led out to the front surface of the interlayer insulating layer 66 (second layer 87) from the contact portion 84. The surface layer portion 85 is integrally formed with the second embedded portion 93 by use of the same material as the second embedded portion 93. More specifically, the surface layer portion 85 extends in a horizontal direction along the front surface of the interlayer insulating layer 66 from a peripheral edge of the fifth contact hole 75 (in this preferred embodiment, a peripheral edge of the upper contact hole 90) and covers a front surface region of the interlayer insulating layer 66 having a certain width from the peripheral edge of the fifth contact hole 75 so as to be in contact with the front surface region thereof.

The end portions 99 of the surface layer portions 85 of the mutually adjacent field plate electrodes 24 oppose each other on the front surface of the interlayer insulating layer 66, with the space 82 kept. It is noted that, in the field plate electrode 24, a portion that is formed of the same material as the surface layer portion 85 (in this preferred embodiment, the surface layer portion 85 and the second embedded portion 93) may be referred to as a main electrode layer, and a portion that is formed of a material different from the main electrode layer and directly connected to the termination region 59 (in this preferred embodiment, the first embedded portion 92) may be referred to as a contact electrode layer.

In this preferred embodiment, the sealing conductive layer 83 is formed as an embedded conductive layer that is embedded in the interlayer insulating layer 66. More specifically, with respect to a thickness direction (vertical direction) of the interlayer insulating layer 66, the sealing conductive layer 83 is formed on the first layer 86 of the interlayer insulating layer 66 and covered by the second layer 87. Also, with respect to the thickness direction (vertical direction) of the interlayer insulating layer 66, the sealing conductive layer 83 is arranged directly on the field insulating layer 62 and opposes an n-type portion (in this preferred embodiment, the drift region 38) of the semiconductor chip 16 across the interlayer insulating layer 66 (first layer 86) and the field insulating layer 62. Also, with respect to a horizontal direction along the front surface of the interlayer insulating layer 66, the sealing conductive layer 83 is arranged in a region between the mutually adjacent field plate electrodes 24. In this preferred embodiment, the sealing conductive layer 83 is arranged in a front surface region of the first layer 86 held between the mutually adjacent contact portions 84.

The sealing conductive layer 83 is formed of a conductive material that is supported by the barrier layer 94 on the first layer 86. This conductive material may be the same material as the contact portion 84 (in this preferred embodiment, the second embedded portion 93). That is, the sealing conductive layer 83 is formed of an aluminum-based metal. More specifically, the sealing conductive layer 83 may contain at least one among aluminum, copper, an aluminum-silicon-copper alloy, an aluminum-silicon alloy and an aluminum-copper alloy. As described so far, where the sealing conductive layer 83 is formed of a metal material, the sealing conductive layer 83 may be referred to as a sealing metal. Also, the sealing conductive layer 83 may be defined to have a laminated structure of the barrier layer 94 and a main conductive layer formed of an aluminum-based metal.

The contact portion 84 of the field plate electrode 24 includes a protrusion portion 100 that selectively protrudes toward the sealing conductive layer 83 in a region on the first layer 86. In FIG. 4A, the protrusion portion 100 and the surface layer portion 85 are led out from the contact portion 84 so as to be arranged in an up/down direction and, therefore, the protrusion portion 100 may be referred to as a first lead-out portion 101 and a portion of the surface layer portion 85 outside the fifth contact hole 75 may be referred to as a second lead-out portion 102. The first lead-out portion 101 is embedded in the interlayer insulating layer 66, and the second lead-out portion 102 is formed in the front surface of the interlayer insulating layer 66. The first lead-out portion 101 and the second lead-out portion 102 oppose each other in the up/down direction across a part of the interlayer insulating layer 66 (in this preferred embodiment, the second layer 87).

Also, a distance D2 from a circumferential surface of the contact portion 84 to a horizontal-direction end portion of the second lead-out portion 102 is longer than a distance D1 from a circumferential surface of the contact portion 84 to a horizontal-direction end portion of the first lead-out portion 101 (protrusion portion 100). For example, the distance D1 may be not less than Opm and not more than 10 μm, and the distance D2 may be not less than 5 μm and not more than 15 μm. Also, the first lead-out portion 101 (protrusion portion 100) extends further outside than the opening 63 of the field insulating layer 62 in a direction along the first principal surface 17. Thereby, an entirety of the opening 63 is covered from above by the contact portion 84 and the first lead-out portion 101 (protrusion portion 100), and also a peripheral edge portion in the vicinity of the opening 63 of the field insulating layer 62 is covered by the first lead-out portion 101.

The second lead-out portion 102 of the surface layer portion 85 is formed as an overlap portion that overlaps with the sealing conductive layer 83 in a thickness direction of the interlayer insulating layer 66. In other words, the sealing conductive layer 83 opposes a part of the surface layer portion 85 in the thickness direction of the interlayer insulating layer 66. Therefore, in FIG. 4A, a central portion of the sealing conductive layer 83 in a horizontal direction opposes the space 82, and both end portions thereof in the horizontal direction oppose the second lead-out portion 102 of the surface layer portion 85.

Also, a first interval W1 between the first lead-out portion 101 (protrusion portion 100) and the sealing conductive layer 83 is narrower than a second interval W2 (width of space 82) between the end portions 99 of the second lead-out portions 102 of the mutually adjacent field plate electrodes 24. For example, the first interval W1 may be not less than 1 μm and the second interval W2 may be not less than 10 μm, and it is preferable that the first interval W1 is not less than 1 μm and not more than 5 μm and the second interval W2 is not less than 10 μm and not more than 15 μm.

Here, with reference to FIG. 6 and FIG. 7, a description will be given of a flat surface pattern of the field plate electrode 24 and that of the sealing conductive layer 83. In FIG. 6 and FIG. 7, for clarification, only constituents necessary for describing the flat surface pattern of the sealing conductive layer 83 are shown, and some of the constituents shown in FIG. 2 to FIG. 5 or other constituents are omitted. Also, in FIG. 6 and FIG. 7, the field plate electrode 24 is shown by hatching and the sealing conductive layer 83 is shown by a broken line.

With reference to FIG. 6 and FIG. 7, in this preferred embodiment, the space 82 between the plurality of field plate electrodes 24 is formed linearly in a plan view. More specifically, each of the field plate electrodes 24 is in an endless shape which surrounds the element forming region 20 and, therefore, the space 82 is also in an endless shape that surrounds the element forming region 20.

The sealing conductive layer 83 is formed linearly in a plan view so as to extend along the linearly formed space 82. For example, as shown in FIG. 6, the sealing conductive layer 83 may be formed in an endless shape in a plan view and may overlap with the space 82 in an endless shape over an entire circumference. Also, as shown in FIG. 7, the plurality of linear (straight line, curved line) sealing conductive layers 83 may be arrayed at an interval from each other along a circumferential direction of the space 82. The sealing conductive layer 83 may include an inner peripheral edge portion 103 that overlaps with the field plate electrode 24 inside in a circumferential direction in a plan view and an outer peripheral edge portion 104 that overlaps with the field plate electrode 24 outside in the circumferential direction. The inner peripheral edge portion 103 and the outer peripheral edge portion 104 may each overlap with the field plate electrode 24 all over in a length direction of the sealing conductive layer 83.

As described above, according to this preferred embodiment, as shown in FIG. 4A, FIG. 6 and FIG. 7, the sealing conductive layer 83 is arranged so as to oppose the space 82 (so as to overlap in a plan view). It is, thereby, possible to prevent intrusion of moisture (OH⁻, H⁺ etc.) into the interlayer insulating layer 66 through the space 82. As a result, it is possible to suppress a change in withstand voltage by polarization due to moisture etc., and also to suppress a decrease in withstand voltage in the vicinity of the field limit region 61.

Also, the second lead-out portion 102 of the field plate electrode 24 and the sealing conductive layer 83 overlap with each other in a thickness direction of the interlayer insulating layer 66. Thereby, as shown in FIG. 6 and FIG. 7, in a region in which the sealing conductive layer 83 is arranged, the space 82 completely overlaps with the sealing conductive layer 83. As a result, it is possible to further increase effects of preventing intrusion of moisture (OH⁻, H⁺, etc.) into the interlayer insulating layer 66.

The field plate electrode 24 also has the protrusion portion 100 (first lead-out portion 101) that protrudes toward the sealing conductive layer 83. Thereby, it is possible to narrow the first interval W1 between the field plate electrode 24 (contact portion 84) and the sealing conductive layer 83. As a result, it is possible to narrow an intrusion channel of moisture (OH⁻, H⁺, etc.) and, therefore, possible to further increase effects of preventing intrusion of moisture (OH⁻, H⁺, etc.) into the interlayer insulating layer 66.

### [Manufacturing Method for Semiconductor Device 1]

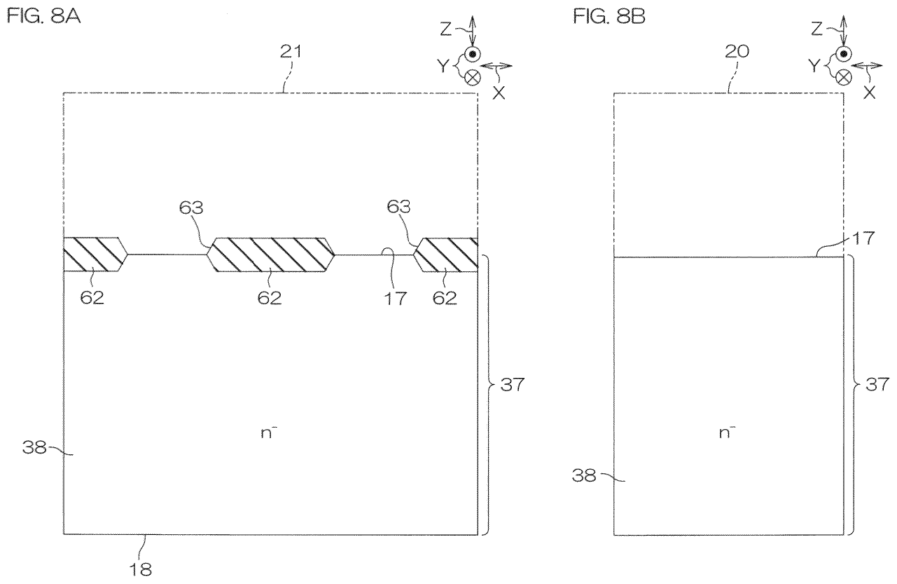

Next, a manufacturing method for the semiconductor device 1 will be described. FIG. 8A, FIG. 8B to FIG. 17A and FIG. 17B are each a drawing for showing some steps of manufacturing the semiconductor device 1 according to a sequence of the steps, mainly showing the steps of manufacturing the element chip 10. Of FIG. 8A, FIG. 8B to FIG. 17A and FIG. 17B, a drawing with the number to which “A” is given shows a cross section corresponding to FIG. 4A, and a drawing with the number to which “B” is given shows a cross section corresponding to FIG. 4B.

In manufacturing the semiconductor device 1, first, the element chip 10 may be prepared. In order to manufacture the element chip 10, the semiconductor substrate 37 in a state of a semiconductor wafer is prepared. Next, a plurality of device forming regions, each of which corresponds to the semiconductor device 1, are set in the semiconductor substrate 37. Each of the device forming regions includes the element forming region 20, the outer region 21 and the scribe region 22. The same structure is formed at the same time in the plurality of device forming regions. A predetermined structure is fabricated in each of the device forming regions and, thereafter, the semiconductor substrate 37 is cut along a peripheral edge of the scribe region 22 in each of the device forming regions. Hereinafter, a description will be given of a structure of one device forming region.

Next, with reference to FIG. 8A and FIG. 8B, the field insulating layer 62 is selectively formed in the first principal surface 17 of the semiconductor substrate 37. In order to form the field insulating layer 62, for example, an entire surface of the first principal surface 17 is subjected to thermal oxidation, thereby forming a thermal oxide film. Next, in the thermal oxide film, a nitride film having an opening for exposing a region in which the field insulating layer 62 is to be formed is selectively formed on the thermal oxide film. Next, the thermal oxide film exposed from the opening of the nitride film is subjected to LOCOS oxidation, thereby forming the field insulating layer 62. After formation of the field insulating layer 62, the nitride film is removed.

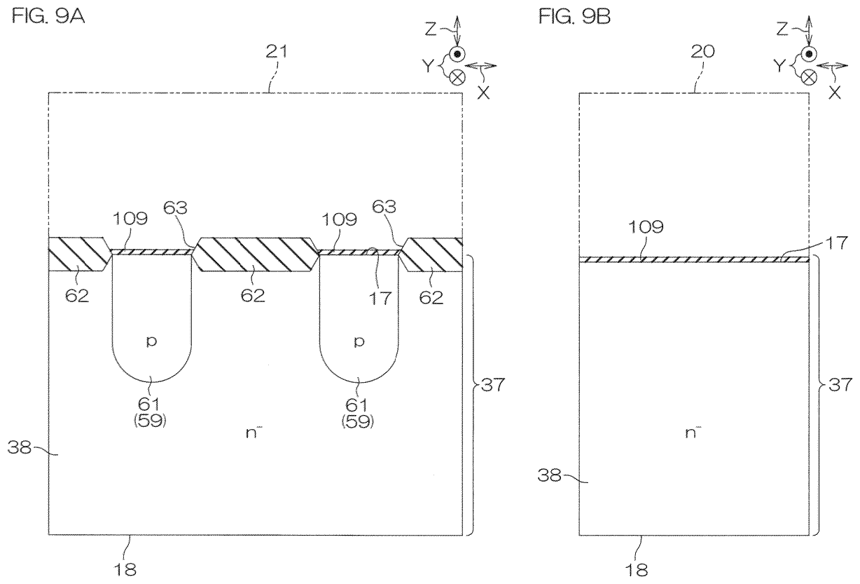

A next step is a step of forming the termination region 59. With reference to FIG. 9A and FIG. 9B, first, an entire surface of the first principal surface 17 is subjected to thermal oxidation, thereby forming a thermal oxide film 109. Next, an ion introducing mask (not shown) having a predetermined pattern is formed on the thermal oxide film 109. The ion introducing mask has a plurality of openings that expose a region in which the plurality of termination regions 59 are to be formed. Next, a p-type impurity is introduced via the ion introducing mask into the semiconductor substrate 37. The plurality of termination regions 59 (in FIG. 9A, the field limit region 61) are, thereby, formed. Thereafter, the ion introducing mask and the thermal oxide film 109 are removed.

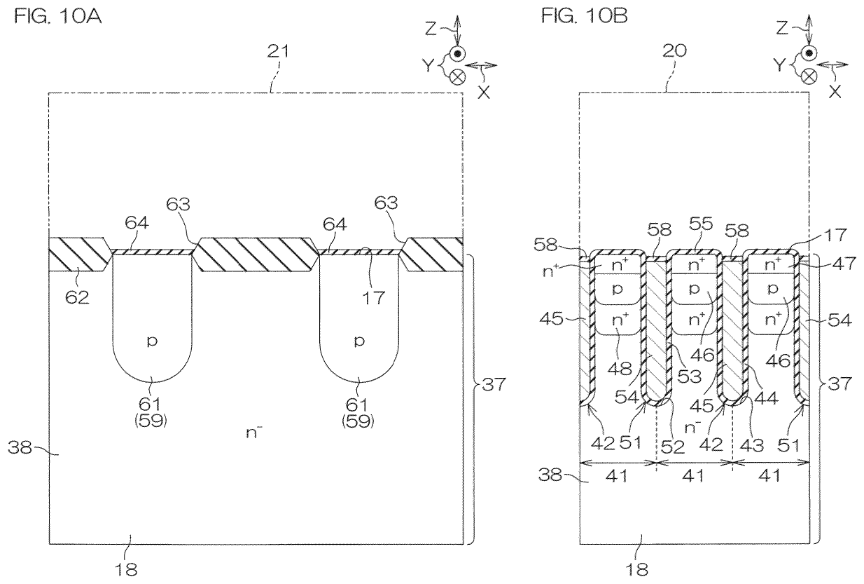

Next, with reference to FIG. 10A and FIG. 10B, the FET structure 41 is formed in the element forming region 20. In order to form the FET structure 41, for example, a hard mask having a predetermined pattern (for example, a CVD oxide film such as a deposited oxide film, etc.) is formed on the first principal surface 17. The hard mask has a plurality of openings, each of which exposes a region in which the gate trench 43 and the emitter trench 52 are to be formed. Next, an unnecessary portion of the semiconductor substrate 37 is removed by an etching method via the hard mask. Thereby, the gate trench 43 and the emitter trench 52 are formed in the element forming region 20. Thereafter, the hard mask is removed.

Next, the gate insulating layer 44, the emitter insulating layer 53 and the first front surface insulating film 55 are formed. The gate insulating layer 44, the emitter insulating layer 53 and the first front surface insulating film 55 may be formed by a CVD method or a thermal oxidation method. Next, the gate electrode layer 45, the emitter potential electrode layer 54, the gate lead-out electrode layer 56 and the emitter lead-out electrode layer 57 (refer to FIG. 5 for all of them) are formed. The gate electrode layer 45 and the emitter potential electrode layer 54 contain a conductive polysilicon. The gate electrode layer 45, the emitter potential electrode layer 54, the gate lead-out electrode layer 56 and the emitter lead-out electrode layer 57 may be formed by a CVD method. Next, for example, by a thermal oxidation method, the second front surface insulating film 58 is formed in the front surfaces of the gate electrode layer 45 and the emitter potential electrode layer 54, and the third front surface insulating film 64 is formed in the first principal surface 17 of the semiconductor substrate 37.

Next, the plurality of n⁺ type carrier storage regions 48 are formed. In this step, first, an ion introducing mask (not shown) having a predetermined pattern is formed on the first principal surface 17. The ion introducing mask has a plurality of openings, each of which exposes a region in which the plurality of carrier storage regions 48 are to be formed. Next, an n-type impurity is introduced into the semiconductor substrate 37 via the ion introducing mask. Next, the n-type impurity is thermally diffused, thereby forming the plurality of carrier storage regions 48. Thereafter, the ion introducing mask is removed.

Next, the plurality of p-type body regions 46 are formed. In this step, first, an ion introducing mask (not shown) having a predetermined pattern is formed on the first principal surface 17. The ion introducing mask has a plurality of openings, each of which exposes a region in which the plurality of body regions 46 are to be formed. Next, a p-type impurity is introduced into the semiconductor substrate 37 via the ion introducing mask. Next, the p-type impurity is thermally diffused, thereby forming the plurality of body regions 46. Thereafter, the ion introducing mask is removed.

Next, the plurality of n⁺ type emitter regions 47 are formed. In this step, first, an ion introducing mask (not shown) having a predetermined pattern is formed on the first principal surface 17. The ion introducing mask has a plurality of opening, each of which exposes a region in which the plurality of emitter regions 47 are to be formed. Next, an n-type impurity is introduced into the semiconductor substrate 37 via the ion introducing mask. Next, the n-type impurity is thermally diffused, thereby forming the plurality of emitter regions 47. Thereafter, the ion introducing mask is removed.

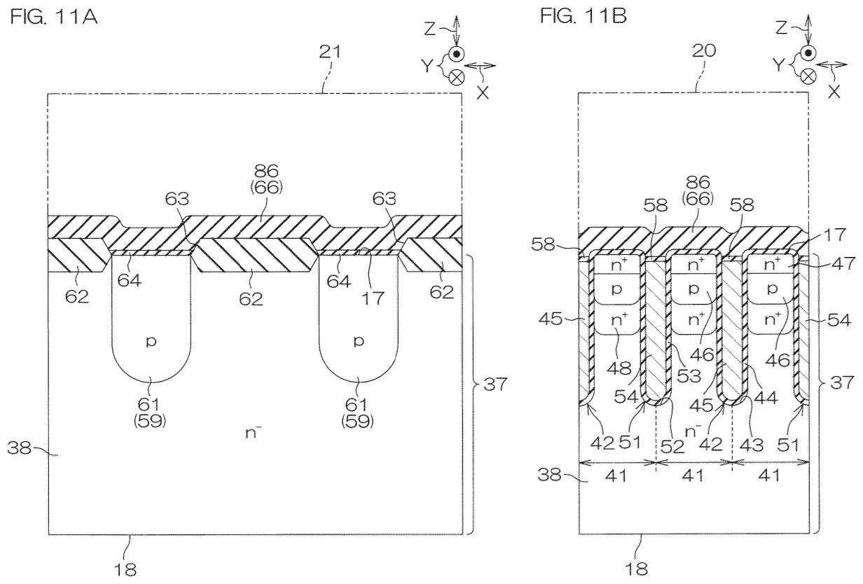

Next, with reference to FIG. 11A and FIG. 11B, the first layer 86 of the interlayer insulating layer 66 is formed so as to cover the first principal surface 17. The first layer 86 may be formed by a CVD method. The first layer 86 may have a thickness that is, for example, not less than 3000 Å and not more than 20000 Å.

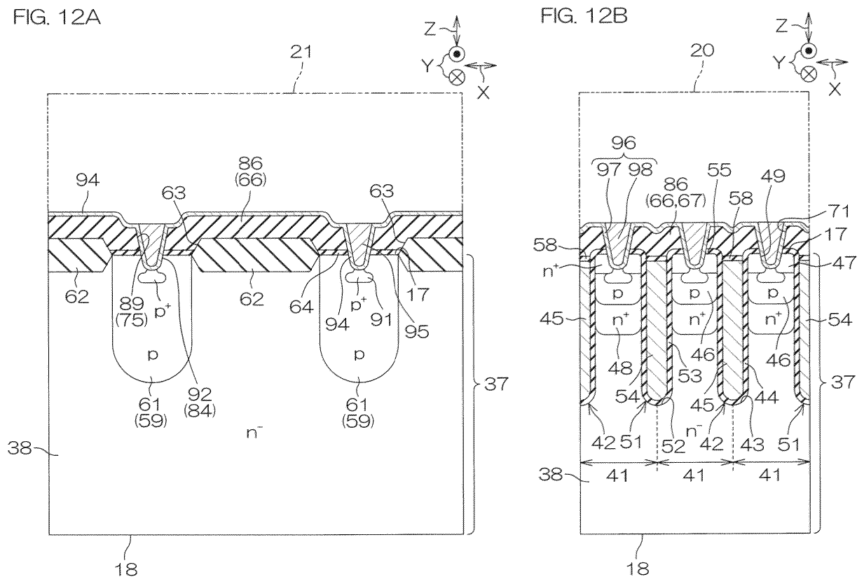

Next, with reference to FIG. 12A and FIG. 12B, the plurality of contact trenches 49 and the plurality of lower contact holes 89 are formed in the first layer 86. Next, the plurality of p⁺ type contact regions 50 and the contact region 91 are formed. In this step, a p-type impurity is introduced into the semiconductor substrate 37 via an ion introducing mask (not shown) having a predetermined pattern through the contact trench 49 and the lower contact hole 89. The plurality of contact regions 50 and the contact region 91 are, thereby, formed. Next, the barrier layer 94 and the barrier layer 97 are formed by, for example, a sputtering method. Next, tungsten is deposited by, for example, a CVD method, and a plug base electrode layer (not shown) is formed so as to cover an entirety of the first principal surface 17. Thereafter, an unnecessary portion of the plug base electrode layer is removed. The unnecessary portion of the plug base electrode layer may be removed by an etching method (etch back). The unnecessary portion of the plug base electrode layer is removed until the first layer 86 is exposed. Thereby, the contact plug 95 and the contact plug 98 are formed.

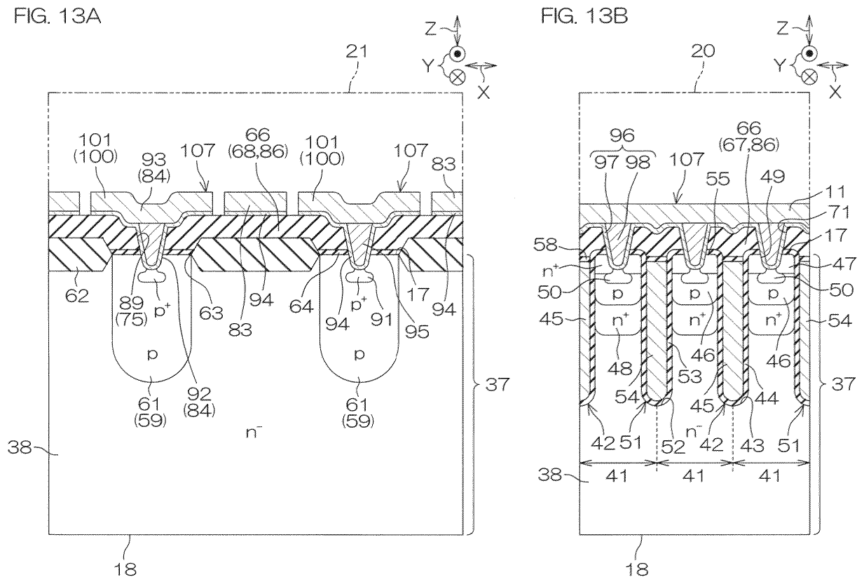

Next, with reference to FIG. 13A and FIG. 13B, a first electrode layer 107 is formed. The first electrode layer 107 is a conductive layer that is to be a base of the sealing conductive layer 83, the contact portion 84 (second embedded portion 93) of the field plate electrode 24, the emitter terminal electrode 11, etc. In this step, the first electrode layer 107 is formed and a patterning is conducted, by which the sealing conductive layer 83 and the second embedded portion 93 are formed in the outer region 21. In the element forming region 20, a lower portion of the emitter terminal electrode 11 is formed. The first electrode layer 107 is formed of an aluminum-based metal. More specifically, the first electrode layer 107 may contain at least one among aluminum, copper, an aluminum-silicon-copper alloy, an aluminum-silicon alloy and an aluminum-copper alloy. Also, the first electrode layer 107 may be formed by a sputtering method.

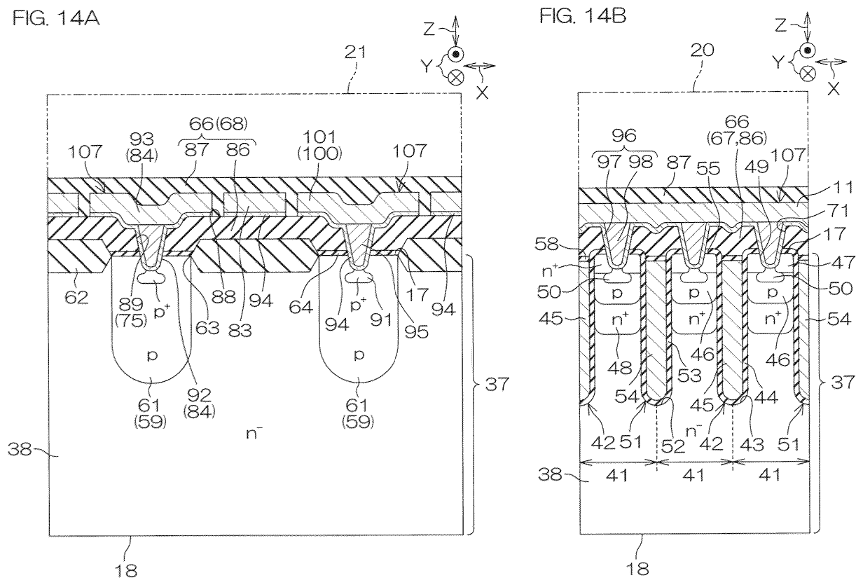

Next, with reference to FIG. 14A and FIG. 14B, the second layer 87 of the interlayer insulating layer 66 is formed on the first layer 86 so as to cover the sealing conductive layer 83, the second embedded portion 93 and the emitter terminal electrode 11. The second layer 87 may be formed by a CVD method. The second layer 87 may have a thickness that is, for example, not less than 1000 Å and not more than 10000 Å. At this time, both of the element forming region 20 and the outer region 21 are covered by the second layer 87.

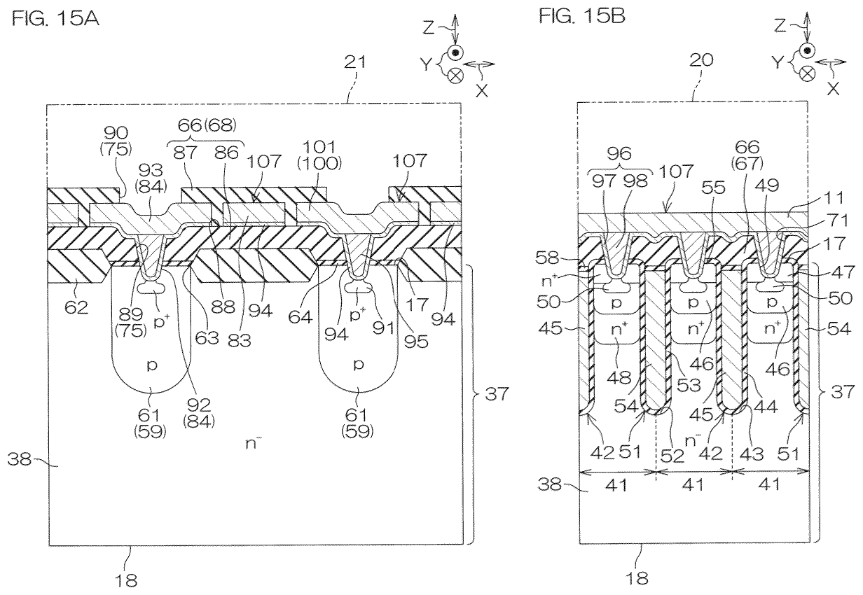

Next, with reference to FIG. 15A and FIG. 15B, the second layer 87 is selectively removed by, for example, an etching method. Thereby, the upper contact hole 90 is formed and the emitter terminal electrode 11 is also exposed in the element forming region 20. In this instance, the contact portion 84 has the protrusion portion 100 and is formed wider than a designed opening width of the upper contact hole 90. Therefore, even where a position at which the upper contact hole 90 is opened deviates in a horizontal direction to some extent, it is possible to expose the contact portion 84.

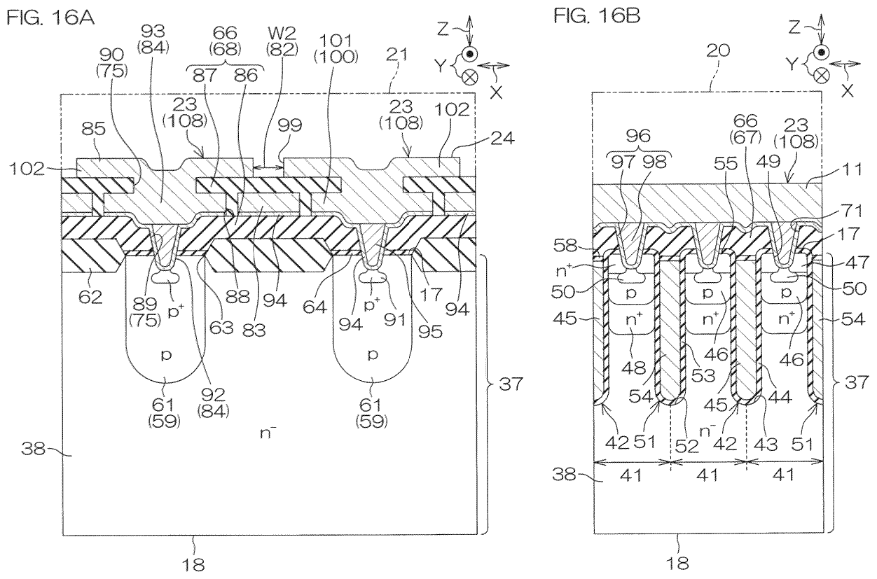

Next, with reference to FIG. 16A and FIG. 16B, a second electrode layer 108 is formed. The second electrode layer 108 is a conductive layer that is to be a base of the surface layer portion 85 of the field plate electrode 24, the emitter terminal electrode 11, etc. In this step, the second electrode layer 108 is formed and a pattering is conducted, by which the surface layer portion 85 is formed in the outer region 21. In the element forming region 20, an upper portion of the emitter terminal electrode 11 is formed, thus resulting in an increase in film thickness of the emitter terminal electrode 11. The second electrode layer 108 is formed of an aluminum-based metal. More specifically, the second electrode layer 108 may contain at least one among aluminum, copper, an aluminum-silicon-copper alloy, an aluminum-silicon alloy and an aluminum-copper alloy. Also, the second-electrode layer 108 may be formed by a sputtering method. Thereby, the front surface electrode 23 is formed.

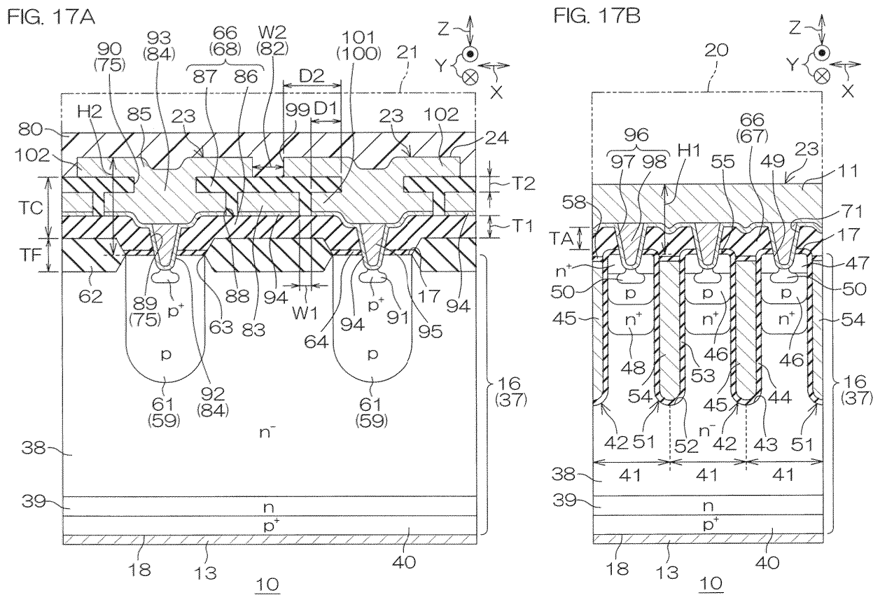

Next, with reference to FIG. 17A and FIG. 17B, the protective layer 80 is formed on the interlayer insulating layer 66 so as to cover the front surface electrode 23. In this step, a material (for example, a liquid of a photosensitive resin consisting of polyimide) of the protective layer 80 is spray-coated onto the semiconductor substrate 37 from above the interlayer insulating layer 66, thereby forming the protective layer 80 of the photosensitive resin. Thereafter, the protective layer 80 is subjected to patterning, thereby forming the opening 81 (refer to FIG. 3) that exposes the emitter terminal electrode 11.

Next, the semiconductor substrate 37 is made thin until it attains a predetermined thickness. The thinning step includes a step of thinning the semiconductor substrate 37 by a grinding method given to the second principal surface 18. The grinding method may be a CMP (Chemical Mechanical Polishing) method. The thinning step may include a step of thinning the semiconductor substrate 37 by an etching method to the second principal surface 18 in place of the grinding method. The etching method may be a wet etching method.

Next, the n-type buffer layer 39 is formed at the surface layer portion of the second principal surface 18. In this step, an n-type impurity is introduced into an entire area of the second principal surface 18 of the semiconductor substrate 37. Thereby, the n-type buffer layer 39 is formed. Next, the p⁺ type collector region 40 is formed at the surface layer portion of the second principal surface 18. In this step, the p-type impurity is introduced into an entire area of the second principal surface 18 of the semiconductor substrate 37. The collector region 40 is, thereby, formed.

Next, the collector terminal electrode 13 is formed in the second principal surface 18. The collector terminal electrode 13 may be formed by a sputtering method. Thereafter, the semiconductor substrate 37 is cut along the scribe region 22 of each of the device forming regions, and the element chip 10 (semiconductor chip 16) is cut out.

Thereafter, each of the element chips 10 is joined to the metal plate 6, and the lead terminal 9 is connected to the emitter terminal electrode 11 and the gate terminal electrode 12 by the conducting wire 15. Then, the element chip 10 is sealed by the package main body 2, thereby providing the semiconductor device 1 shown in FIG. 1.

### [Withstand-Voltage Decrease Preventive Structure of Element Chip 10 (Second Mode)]

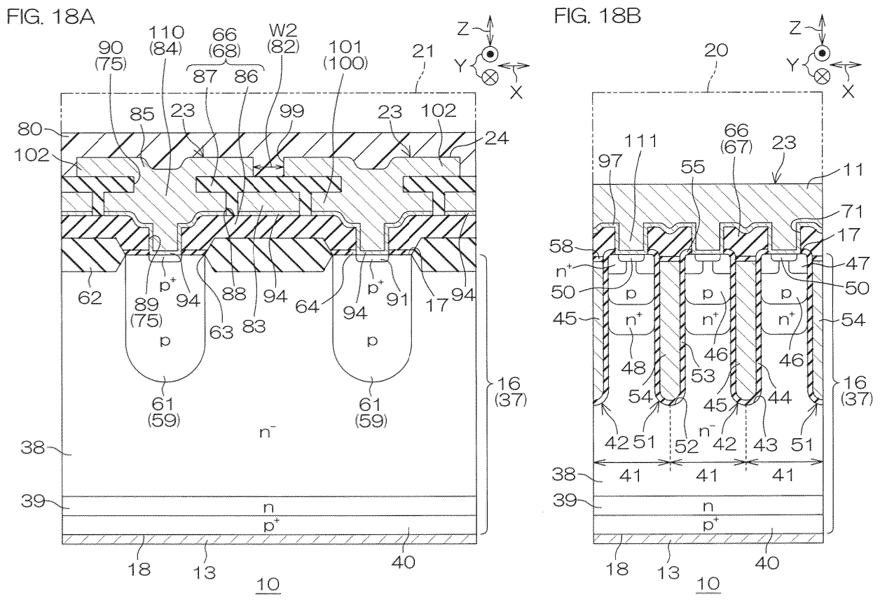

FIG. 18A and FIG. 18B are respectively a schematic cross sectional view of the element chip 10 in the outer region 21 and a schematic cross sectional view of that in the element forming region 20. FIG. 18A and FIG. 18B are drawings respectively corresponding to FIG. 4A and FIG. 4B aforementioned. FIG. 18A and FIG. 18B show a second mode of the withstand-voltage decrease preventive structure of the element chip 10. Hereinafter, a description will be given of the constituents different from those of FIG. 4A and FIG. 4B, and a description of the constituents common to those of FIG. 4A and FIG. 4B will be omitted in FIG. 18A and FIG. 18B by using the same reference signs as those of FIG. 4A and FIG. 4B.

The element chip 10 shown in FIG. 18A and FIG. 18B has an embedded portion 110 that is formed by a single conductive material in which the contact portion 84 of the field plate electrode 24 is integrally embedded in the first layer 86 and the second layer 87 of the interlayer insulating layer 66. Also, an emitter plug electrode 111 is integrally formed with the emitter terminal electrode 11 by use of a single conductive material. This point is different from the element chip 10 shown in FIG. 4A and FIG. 4B that has the contact portion 84 including the first embedded portion 92 and the second embedded portion 93 and that has the emitter plug electrode 96 including the contact plug 98 (tungsten plug).

The embedded portion 110 and the emitter plug electrode 111 are formed of an aluminum-based metal. More specifically, the embedded portion 110 and the emitter plug electrode 111 may contain at least one among aluminum, copper, an aluminum-silicon-copper alloy, an aluminum-silicon alloy and an aluminum-copper alloy.

The barrier layer 94 is interposed between the embedded portion 110, the interlayer insulating layer 66 (in this preferred embodiment, the first layer 86) and the first principal surface 17. The embedded portion 110 is connected via the barrier layer 94 to the contact region 91, and the barrier layer 97 is interposed between the emitter plug electrode 111, the interlayer insulating layer 66 and the first principal surface 17. The emitter plug electrode 111 is connected via the barrier layer 97 to the emitter region 47 and the contact region 50.

### [Withstand-Voltage Decrease Preventive Structure of Element Chip 10 (Third Mode)]

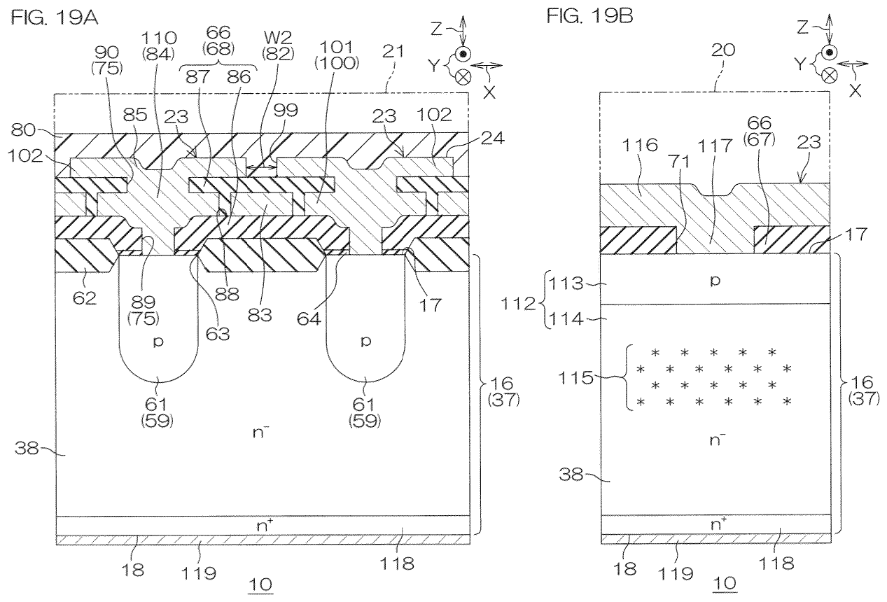

FIG. 19A and FIG. 19B are respectively a schematic cross sectional view of the element chip 10 in the outer region 21 and a schematic cross sectional view of that in the element forming region 20. FIG. 19A and FIG. 19B respectively correspond to FIG. 18A and FIG. 18B aforementioned. FIG. 19A and FIG. 19B show a third mode of the withstand-voltage decrease preventive structure of the element chip 10. Hereinafter, a description will be given of the constituents different from those of FIG. 18A and FIG. 18B, and a description of the constituents common to those of FIG. 18A and FIG. 18B will be omitted in FIG. 19A and FIG. 19B by using the same reference signs as those of FIG. 18A and FIG. 18B.

In the element chip 10 shown in FIG. 19A and FIG. 19B, first, the barrier layer 94 is omitted, which is different from the element chip 10 shown in FIG. 18A and FIG. 18B. Thereby, the embedded portion 110 is directly connected to the field limit region 61.

Also, a diode structure 112 is formed in place of the FET structure 41 in the element forming region 20. The diode structure 112 includes a p-type anode region 113 that is formed at a surface layer portion of the first principal surface 17 and an n-type cathode region 114 that is formed by a part of the drift region 38 at the surface layer portion of the second principal surface 18. A p-type impurity concentration of the anode region 113 may be not less than 1.0×10¹³ cm⁻³ and not more than 1.0×10¹⁷ cm⁻³. An n-type impurity concentration of the cathode region 114 may be not less than 1.0×10¹³ cm⁻³ and not more than 1.0×10¹⁵ cm⁻³. Also, a crystal defect 115 may be formed in the cathode region 114, for example, by diffusion of heavy metals (for example, Au, Pt, etc.), electron beam irradiation, etc. Thereby, the diode structure 112 may be formed as a fast recovery diode (high speed diode) in which a reverse recovery time (trr) is made relatively short.

In the element forming region 20, the front surface electrode 23 may include an anode terminal electrode 116. The anode terminal electrode 116 is formed of an aluminum-based metal. More specifically, the anode terminal electrode 116 may contain at least one among aluminum, copper, an aluminum-silicon-copper alloy, an aluminum-silicon alloy and an aluminum-copper alloy. The anode terminal electrode 116 includes a contact portion 117 that is embedded in the first contact hole 71 and is electrically connected to the anode region 113 by the contact portion 117 that is directly in contact with the anode region 113.

The element forming region 20 also includes an n⁺ type contact region 118 that is formed at the surface layer portion of the second principal surface 18 of the semiconductor chip 16. The contact region 118 is exposed from the second principal surface 18. The contact region 118 may be formed in an entire area of the semiconductor chip 16 at the surface layer portion of the second principal surface 18. An n-type impurity concentration of the contact region 118 may be not less than 1.0×10¹⁹ cm⁻³ and not more than 1.0×10²⁰ cm⁻³.

The second principal surface 18 of the semiconductor chip 16 includes a cathode terminal electrode 119 as an example of a rear surface electrode. The cathode terminal electrode 119 forms an ohmic contact with the second principal surface 18 (contact region 118). The cathode terminal electrode 119 may include at least one among a Ti layer, an Ni layer, an Au layer, an Ag layer and an Al layer. The cathode terminal electrode 119 may have a single layered structure that includes a Ti layer, an Ni layer, an Au layer, an Ag layer or an Al layer. The cathode terminal electrode 119 may have a laminated structure in which at least two among a Ti layer, an Ni layer, an Au layer, an Ag layer and an Al layer are laminated in an arbitrary mode.

### [Withstand-Voltage Decrease Preventive Structure of Element Chip 10 (Fourth Mode)]

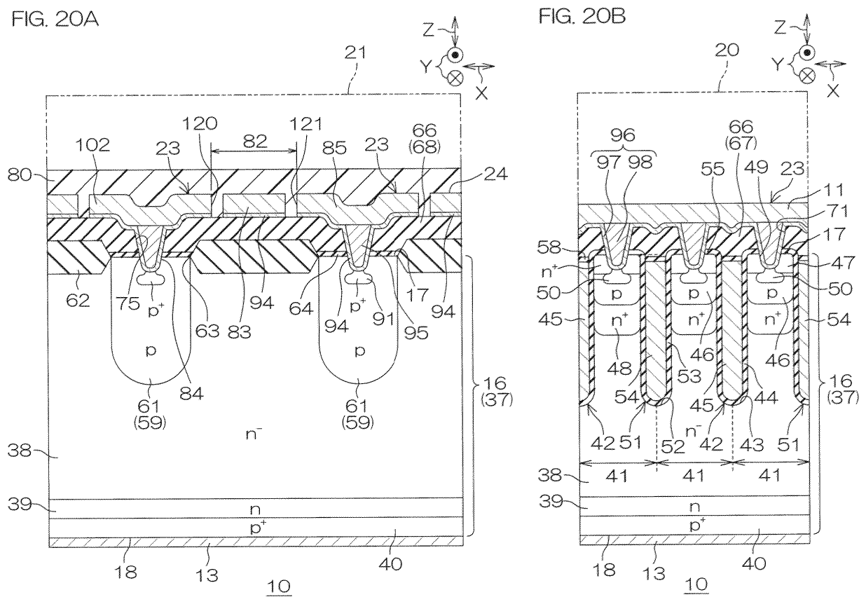

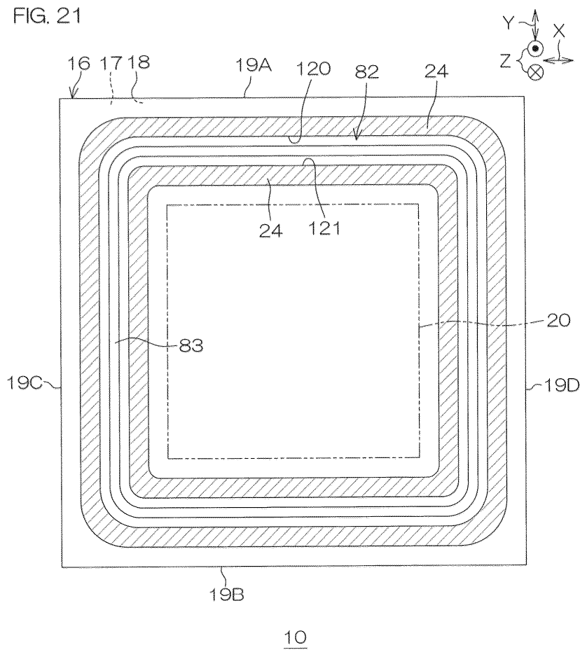

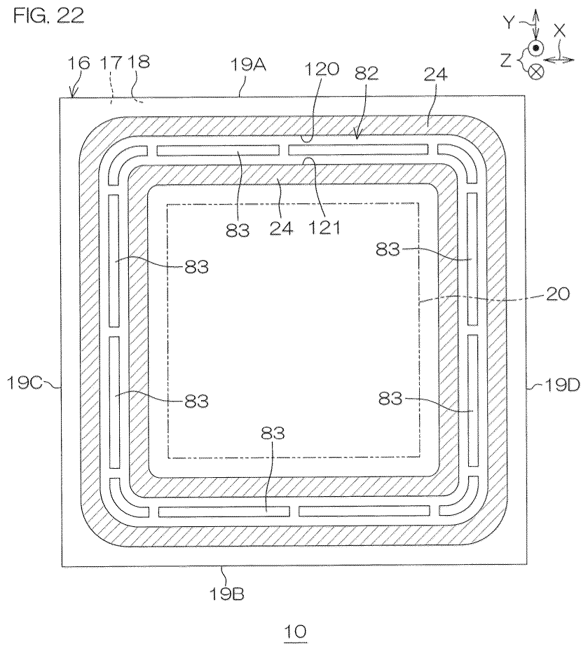

FIG. 20A and FIG. 20B are respectively a schematic cross sectional view of the element chip 10 in the outer region 21 and a schematic cross sectional view of that in the element forming region 20. FIG. 20A and FIG. 20B respectively correspond to FIG. 4A and FIG. 4B aforementioned. FIG. 20A and FIG. 20B show a fourth mode of the withstand-voltage decrease preventive structure of the element chip 10. FIG. 21 and FIG. 22 are each a drawing that schematically shows a flat surface pattern of the sealing conductive layer 83. Hereinafter, a description will be given of the constituents different from those of FIG. 4A and FIG. 4B, and a description of the constituents common to those of FIG. 4A and FIG. 4B will be omitted in FIG. 20A and FIG. 20B by using the same reference signs as those of FIG. 4A and FIG. 4B.

In the element chip 10 shown in FIG. 20A and FIG. 20B, the interlayer insulating layer 66 is not formed in a laminated structure of the first layer 86 and the second layer 87 but formed in a single layered structure. The front surface electrode 23 and the sealing conductive layer 83 are both formed in a front surface of this interlayer insulating layer 66. The sealing conductive layer 83 is arranged at the space 82 between the field plate electrodes 24 that are adjacent to each other.

Also, the sealing conductive layer 83 is arranged directly on the field insulating layer 62 with respect to a thickness direction (vertical direction) of the interlayer insulating layer 66 and opposes an n-type portion (in this preferred embodiment, the drift region 38) of the semiconductor chip 16 across the interlayer insulating layer 66 and the field insulating layer 62.

Here, with reference to FIG. 21 and FIG. 22, a description will be given of a flat surface pattern of the field plate electrode 24 and that of the sealing conductive layer 83 shown in FIG. 20A. In FIG. 21 and FIG. 22, for clarification, only a constituent that is necessary for describing the flat surface pattern of the sealing conductive layer 83 is shown. Also, in FIG. 21 and FIG. 22, hatching is given to the field plate electrode 24.

With reference to FIG. 21 and FIG. 22, in this preferred embodiment, the space 82 between the plurality of field plate electrodes 24 is formed linearly in a plan view. More specifically, each of the field plate electrodes 24 is in an endless shape that surrounds the element forming region 20 and, therefore, the space 82 is also in an endless shape that surrounds the element forming region 20.

The sealing conductive layer 83 is formed linearly in a plan view such as to extend along the linear space 82. For example, as shown in FIG. 21, the sealing conductive layer 83 may be formed in an endless shape in a plan view and may overlap with the space 82 in an endless shape over an entire circumference thereof. Also, as shown in FIG. 22, a plurality of linear (straight line, curved line) sealing conductive layers 83 may be arrayed at an interval from each other along a circumferential direction of the space 82. The sealing conductive layer 83 is arranged in a region held between an inner peripheral edge portion 120 and an outer peripheral edge portion 121 of the field plate electrode 24 in a plan view. The sealing conductive layer 83 is formed at an interval from both of the inner peripheral edge portion 120 and the outer peripheral edge portion 121. Thereby, the sealing conductive layer 83 has a width narrower than the space 82.

According to this preferred embodiment, as shown in FIG. 20A, FIG. 21 and FIG. 22, the sealing conductive layer 83 is arranged at the space 82. It is, thereby, possible to prevent intrusion of moisture (OH⁻, H⁺, etc.) into the interlayer insulating layer 66 through the space 82. As a result, it is possible to suppress a change in withstand voltage by polarization due to moisture, etc., and also possible to suppress a decrease in withstand voltage in the vicinity of the field limit region 61.

### [Withstand-Voltage Decrease Preventive Structure of Element Chip 10 (Fifth Mode)]

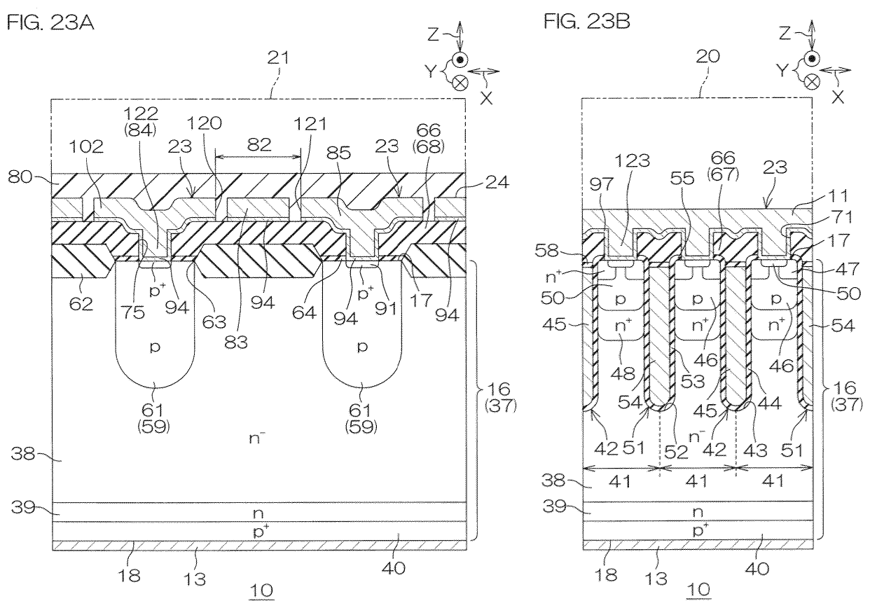

FIG. 23A and FIG. 23B are respectively a schematic cross sectional view of the element chip 10 in the outer region 21 and a schematic cross sectional view of that in the element forming region 20. FIG. 23A and FIG. 23B are drawings respectively corresponding to FIG. 20A and FIG. 20B aforementioned. FIG. 23A and FIG. 23B show a fifth mode of the withstand-voltage decrease preventive structure of the element chip 10. Hereinafter, a description will be given of the constituents different from those of FIG. 20A and FIG. 20B, and a description of the constituents common to those of FIG. 20A and FIG. 20B will be omitted in FIG. 23A and FIG. 23B by using the same reference signs as those of FIG. 20A and FIG. 20B.

In the element chip 10 shown in FIG. 23A and FIG. 23B, the contact portion 84 of the field plate electrode 24 has an embedded portion 122 that is formed by a single conductive material integrally embedded in the interlayer insulating layer 66. Also, an emitter plug electrode 123 is integrally formed with the emitter terminal electrode 11 by a single conductive material. This is different from the element chip 10 shown in FIG. 20A and FIG. 20B having the contact portion 84 that includes the contact plug 95 (tungsten plug) and the emitter plug electrode 96 that includes the contact plug 98 (tungsten plug).

The embedded portion 122 and the emitter plug electrode 123 are formed of an aluminum-based metal. More specifically, the embedded portion 122 and the emitter plug electrode 123 may contain at least one among aluminum, copper, an aluminum-silicon-copper alloy, an aluminum-silicon alloy and an aluminum-copper alloy.

The barrier layer 94 is interposed between the embedded portion 122, the interlayer insulating layer 66 and the first principal surface 17. The embedded portion 122 is connected via the barrier layer 94 to the contact region 91, and the barrier layer 97 is interposed between the emitter plug electrode 123, the interlayer insulating layer 66 and the first principal surface 17. The emitter plug electrode 123 is connected via the barrier layer 97 to the emitter region 47 and the contact region 50.

### [Withstand-Voltage Decrease Preventive Structure of Element Chip 10 (Sixth Mode)]

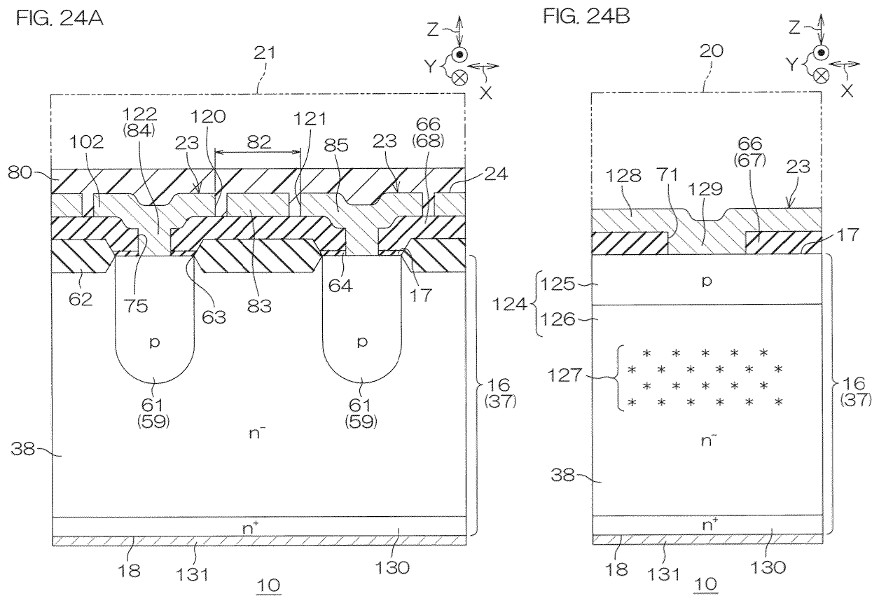

FIG. 24A and FIG. 24B are respectively a schematic cross sectional view of the element chip 10 in the outer region 21 and a schematic cross sectional view of that in the element forming region 20. FIG. 24A and FIG. 24B are drawings respectively corresponding to FIG. 23A and FIG. 23B aforementioned. FIG. 24A and FIG. 24B show a sixth mode of the withstand-voltage decrease preventive structure of the element chip 10. Hereinafter, a description will be given of the constituents different from those of FIG. 23A and FIG. 23B, and a description of the constituents common to those of FIG. 23A and FIG. 23B will be omitted in FIG. 24A and FIG. 24B by using the same reference signs as those of FIG. 23A and FIG. 23B.

In the element chip 10 shown in FIG. 24A and FIG. 24B, first, the barrier layer 94 is omitted, which is different from the element chip 10 shown in FIG. 23A and FIG. 23B. Thereby, the embedded portion 122 is directly connected to the field limit region 61.

Also, in the element forming region 20, a diode structure 124 is formed in place of the FET structure 41. The diode structure 124 includes a p-type anode region 125 that is formed at a surface layer portion of the first principal surface 17 and an n-type cathode region 126 that is formed at the surface layer portion of the second principal surface 18 by a part of the drift region 38. A p-type impurity concentration of the anode region 125 may be not less than 1.0×10¹³ cm⁻³ and not more than 1.0×10¹⁶ cm⁻³. An n-type impurity concentration of the cathode region 126 may be not less than 1.0×10¹³ cm⁻³ and not more than 1.0×10¹⁵ cm⁻³. Also, in the cathode region 126, a crystal defect 127 may be formed, for example, by diffusion of heavy metals (for example, Au, Pt, etc.), electron beam irradiation, etc. Thereby, the diode structure 124 may be formed as a fast recovery diode (high speed diode) in which a reverse recovery time (trr) is made relatively short.

In the element forming region 20, the front surface electrode 23 may include an anode terminal electrode 128. The anode terminal electrode 128 is formed of an aluminum-based metal. More specifically, the anode terminal electrode 128 may contain at least one among aluminum, copper, an aluminum-silicon-copper alloy, an aluminum-silicon alloy and an aluminum-copper alloy. The anode terminal electrode 128 includes a contact portion 129 that is embedded in the first contact hole 71 and is electrically connected to the anode region 125 by the contact portion 129 that is directly in contact with the anode region 125.

The element forming region 20 also includes an n⁺ type contact region 130 that is formed at the surface layer portion of the second principal surface 18 of the semiconductor chip 16. The contact region 130 is exposed from the second principal surface 18. The contact region 130 may be formed in an entire area of the semiconductor chip 16 at the surface layer portion of the second principal surface 18. An n-type impurity concentration of the contact region 130 may be not less than 1.0×10¹⁹ cm⁻³ and not more than 1.0×10²⁰ cm⁻³.

A cathode terminal electrode 131 is included as an example of the rear surface electrode in the second principal surface 18 of the semiconductor chip 16. The cathode terminal electrode 131 forms an ohmic contact with the second principal surface 18 (contact region 130). The cathode terminal electrode 131 may include at least one among a Ti layer, an Ni layer, an Au layer, an Ag layer and an Al layer. The cathode terminal electrode 131 may have a single layered structure that includes a Ti layer, an Ni layer, an Au layer, an Ag layer or an Al layer. The cathode terminal electrode 131 may have a laminated structure in which at least two among a Ti layer, an Ni layer, an Au layer, an Ag layer and an Al layer are laminated in an arbitrary mode.

### [Withstand-Voltage Decrease Preventive Structure of Element Chip 10 (Seventh Mode)]

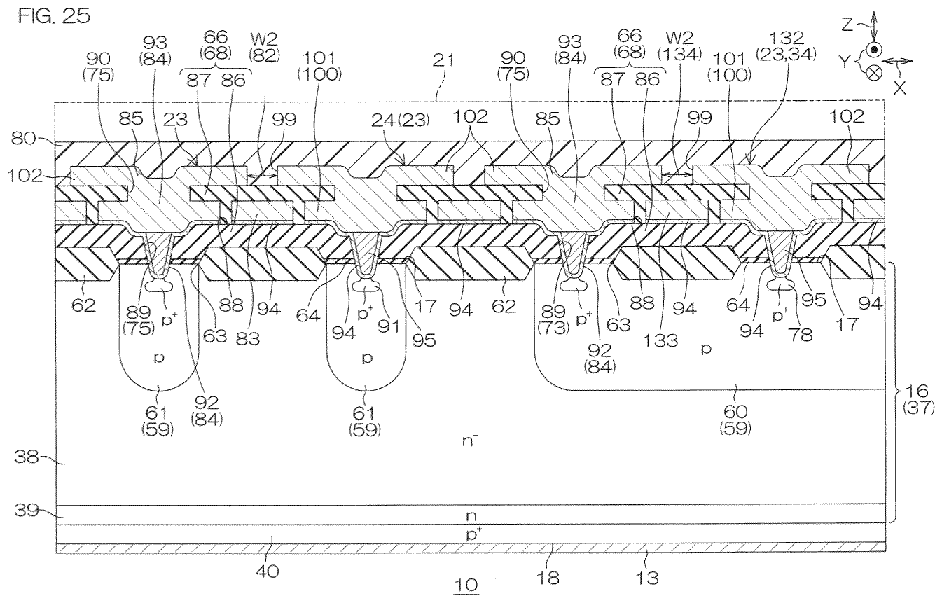

FIG. 25 is a schematic cross sectional view of the element chip 10 in the outer region 21. FIG. 25 shows a seventh mode of the withstand-voltage decrease preventive structure of the element chip 10. Hereinafter, a description will be given of the constituents different from those of FIG. 4A and FIG. 4B, and a description of the constituents common to those of FIG. 4A and FIG. 4B will be omitted in FIG. 25 by using the same reference signs as those of FIG. 4A and FIG. 4B.

FIG. 25 shows an example in which, for example, where emitter potential electrodes 132 such as the emitter routing portion 34 are formed adjacent to each other, the sealing conductive layer 133 may be formed so as to oppose a space 134 between these emitter potential electrodes 132. The emitter potential electrode 132 is connected to the RESURF layer 60 of the termination region 59. Therefore, the sealing conductive layer 133 is able to suppress a decrease in withstand voltage in the vicinity of the RESURF layer 60.

### [Withstand-Voltage Decrease Preventive Structure of Element Chip 10 (Eighth Mode)]

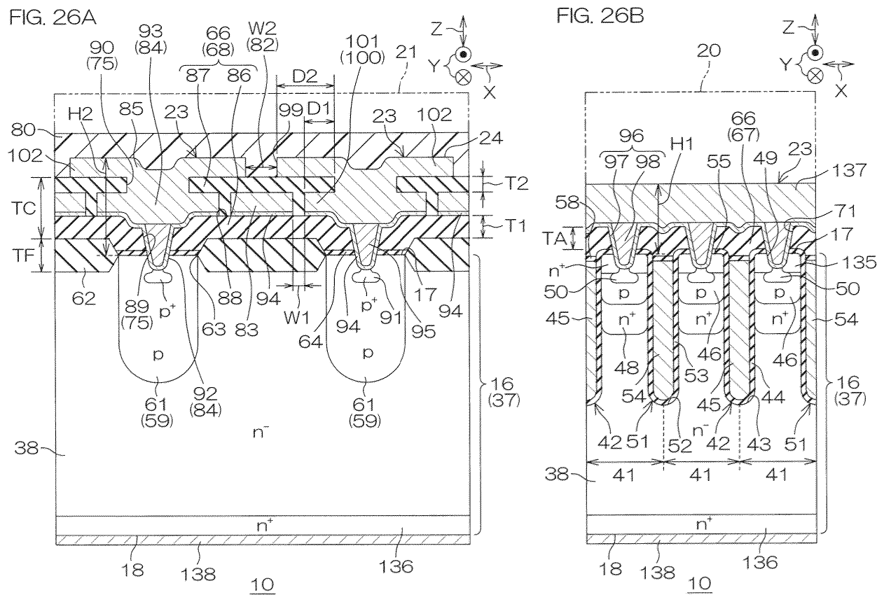

FIG. 26A and FIG. 26B are respectively a schematic cross sectional view of the element chip 10 in the outer region 21 and a schematic cross sectional view of that in the element forming region 20. FIG. 26A and FIG. 26B are drawings respectively corresponding to FIG. 4A and FIG. 4B aforementioned. FIG. 26A and FIG. 26B show an eighth mode of the withstand-voltage decrease preventive structure of the element chip 10. Hereinafter, a description will be given of the constituents different from those of FIG. 4A and FIG. 4B, and a description of the constituents common to those of FIG. 4A and FIG. 4B will be omitted in FIG. 26A and FIG. 26B by using the same reference signs as those of FIG. 4A and FIG. 4B.

In the element chip shown in FIG. 26A and FIG. 26B, the FET structure 41 is formed not as the IGBT structure but as the MOSFET structure. In this case, the emitter region 47 may be an n⁺ type source region 135 and the collector region 40 may be an n⁺ type drain region 136. Also, the emitter terminal electrode 11 may be a source terminal electrode 137 and the collector terminal electrode 13 may be a drain terminal electrode 138.

### [Entire Configuration of Semiconductor Module 200]

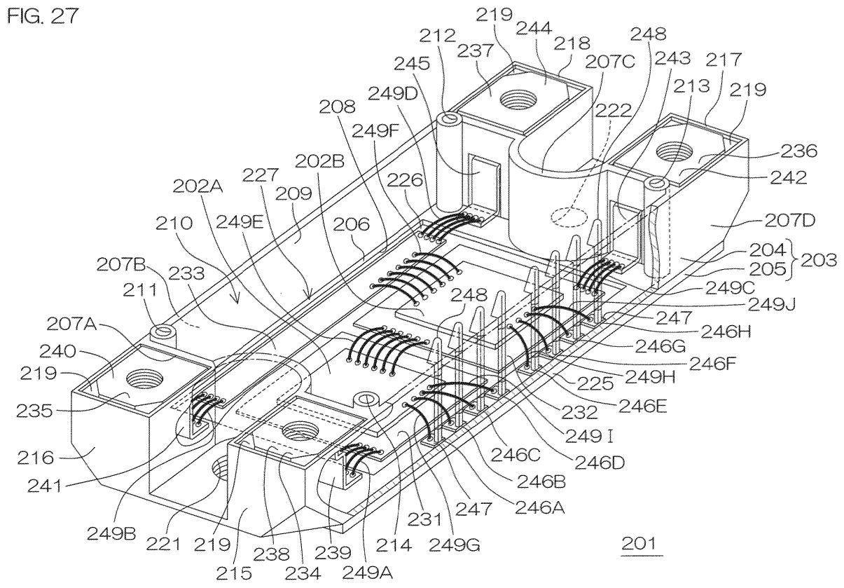

FIG. 27 is a schematic external view of a semiconductor module 200 according to a preferred embodiment of the present disclosure.

One or two or more semiconductor chips 202 are incorporated into a semiconductor module 201.

In this mode, the semiconductor module 201 has a structure into which the two semiconductor chips 202 are incorporated. Hereinafter, for the sake of convenience, the two semiconductor chips 202 are respectively referred to as a first semiconductor chip 202A and a second semiconductor chip 202B. The aforementioned element chip 10 may be applied to the first semiconductor chip 202A and the second semiconductor chip 202B.

With reference to FIG. 27, the semiconductor module 201 includes a housing 203 that houses the first semiconductor chip 202A and the second semiconductor chip 202B. The housing 203 includes a resin case 204 and a supporting substrate 205. The supporting substrate 205 is a substrate that supports the first semiconductor chip 202A and the second semiconductor chip 202B.

The resin case 204 includes a bottom wall 206 and side walls 207A, 207B, 207C, 207D. The bottom wall 206 is formed in a quadrangle shape (in this mode, a rectangular shape) in a plan view as viewed in its normal direction. A through hole 208 is formed in the bottom wall 206. The through hole 208 is formed in a region at an interval internally from a peripheral edge of the bottom wall 206. In this mode, the through hole 208 is formed in a quadrangle shape (in this mode, a rectangular shape) in a plan view. The side walls 207A to 207D are erected from the peripheral edge of the bottom wall 206 toward the opposite side of the bottom wall 206. The side walls 207A to 207D demarcate an opening 209 at the opposite side of the bottom wall 206. The side walls 207A to 207D demarcate an inner space 210 with the bottom wall 206.

The side wall 207A and the side wall 207C extend along a short direction of the bottom wall 206. The side wall 207A and the side wall 207C oppose each other in a longitudinal direction of the bottom wall 206. The side wall 207B and the side wall 207D extend along the longitudinal direction of the bottom wall 206. The side wall 207B and the side wall 207D oppose each other in the short direction of the bottom wall 206.

Bolt insertion holes 211, 212, 213, 214 are individually formed at four corner portions of the inner space 210. The inner space 210 is closed by a lid member or a sealing member (for example, sealing gel) that is not shown. The lid member is fixed to the bolt insertion holes 211, 212, 213, 214 by use of a bolt.

The resin case 204 includes a plurality of terminal supporting portions 215, 216, 217, 218. In this mode, the plurality of terminal supporting portions 215 to 218 include a first terminal supporting portion 215, a second terminal supporting portion 216, a third terminal supporting portion 217 and a fourth terminal supporting portion 218. The first terminal supporting portion 215 and the second terminal supporting portion 216 are attached to an outer wall of the side wall 207A. In this mode, the first terminal supporting portion 215 and the second terminal supporting portion 216 are integrally formed with the outer wall of the side wall 207A.

The first terminal supporting portion 215 and the second terminal supporting portion 216 are formed at an interval from each other in the short direction. The first terminal supporting portion 215 and the second terminal supporting portion 216 are each formed in a block shape. The first terminal supporting portion 215 and the second terminal supporting portion 216 each protrude from the outer wall of the side wall 207A toward outside in the longitudinal direction.

The third terminal supporting portion 217 and the fourth terminal supporting portion 218 are attached to the side wall 207C. In this mode, the third terminal supporting portion 217 and the fourth terminal supporting portion 218 are integrally formed with an outer wall of the side wall 207C.

The third terminal supporting portion 217 and the fourth terminal supporting portion 218 are formed at an interval from each other in the short direction. The third terminal supporting portion 217 and the fourth terminal supporting portion 218 are each formed in a block shape. The third terminal supporting portion 217 and the fourth terminal supporting portion 218 each protrude from the side wall 207C toward outside in the longitudinal direction.

The first terminal supporting portion 215, the second terminal supporting portion 216, the third terminal supporting portion 217 and the fourth terminal supporting portion 218 each have a supporting wall 219. Each of the supporting walls 219 is positioned at a region that is further at the opening 209 side than the bottom wall 206. Each of the supporting walls 219 is formed in a quadrangle shape in a plan view.

A first bolt insertion hole 221 is formed in a region between the first terminal supporting portion 215 and the second terminal supporting portion 216. A second bolt insertion hole 222 is formed in a region between the third terminal supporting portion 217 and the fourth terminal supporting portion 218.

The supporting substrate 205 includes a heat dissipation plate 225, an insulating material 226 and a circuit portion 227. The supporting substrate 205 is attached to an outer surface of the resin case 204 so that the circuit portion 227 is exposed from the through hole 208 of the bottom wall 206. The supporting substrate 205 may be attached to the outer surface of the resin case 204 by the heat dissipation plate 225 that is bonded to the outer surface of the resin case 204.

The heat dissipation plate 225 may be a metal plate. The heat dissipation plate 225 may be an insulating plate covered by a metal film. The heat dissipation plate 225 is formed in a quadrangle shape (in this mode, a rectangular shape) in a plan view as viewed from its normal direction.

The insulating material 226 is formed on the heat dissipation plate 225. The insulating material 226 may be a mounting substrate that includes an insulating material. The insulating material 226 may be an insulating film that is formed as a film on the heat dissipation plate 225.

The circuit portion 227 is formed on the heat dissipation plate 225 via the insulating material 226. The circuit portion 227 includes a plurality of wirings 231, 232, 233, the first semiconductor chip 202A and the second semiconductor chip 202B. In this mode, the wirings 231 to 233 include a first collector wiring 231, a second collector wiring 232 and an emitter wiring 233.

The first collector wiring 231 is formed as a plate or as a film. The first collector wiring 231 is formed in a quadrangle shape in a plan view. The first collector wiring 231 is arranged in a region of the heat dissipation plate 225 at one side (side wall 207A side) in the longitudinal direction and in a region thereof at one side (side wall 207D side) in the short direction.

The second collector wiring 232 is formed as a plate or as a film. The second collector wiring 232 is formed in a quadrangle shape in a plan view. The second collector wiring 232 is arranged at an interval from the first collector wiring 231 in a region of the heat dissipation plate 225 at the other side (side wall 207C side) in the longitudinal direction and in a region thereof at one side (side wall 207D side) in the short direction.

The emitter wiring 233 is formed as a plate or as a film. The emitter wiring 233 is formed in a quadrangle shape in a plan view. In this mode, the emitter wiring 233 is formed in a rectangular shape extending along the longitudinal direction of the heat dissipation plate 225. The emitter wiring 233 is arranged at an interval from the first collector wiring 231 and the second collector wiring 232 in a region of the heat dissipation plate 225 at the other side (side wall 207B side) in the short direction.

The first semiconductor chip 202A is arranged on the first collector wiring 231 in a posture that the collector terminal electrode 13 opposes the heat dissipation plate. The collector terminal electrode 13 of the first semiconductor chip 202A is joined to the first collector wiring 231 via a conductive joining material.

Thereby, the collector terminal electrode 13 of the first semiconductor chip 202A is electrically connected to the first collector wiring 231. The conductive joining material may include a solder or a conductive paste.

The second semiconductor chip 202B is arranged on the second collector wiring 232 in a posture that the collector terminal electrode 13 opposes the heat dissipation plate. The collector terminal electrode 13 of the second semiconductor chip 202B is joined via the conductive joining material to the second collector wiring 232.

Thereby, the collector terminal electrode 13 of the second semiconductor chip 202B is electrically connected to the second collector wiring 232. The conductive joining material may include a solder or a conductive paste.

The semiconductor module 201 includes a plurality of terminals 234, 235, 236, 237. The plurality of terminals 234 to 237 includes a collector terminal 234, a first emitter terminal 235, a common terminal 236 and a second emitter terminal 237.

The collector terminal 234 is arranged at the first terminal supporting portion 215. The collector terminal 234 is electrically connected to the first collector wiring 231. The collector terminal 234 includes a first region 238 and a second region 239. The first region 238 of the collector terminal 234 is positioned outside the inner space 210. The second region 239 of the collector terminal 234 is positioned inside the inner space 210.

The first region 238 of the collector terminal 234 is supported by the supporting wall 219 of the first terminal supporting portion 215. The second region 239 of the collector terminal 234 penetrates through the side wall 207A from the first region 238 and is led out into the inner space 210. The second region 239 of the collector terminal 234 is electrically connected to the first collector wiring 231.

The first emitter terminal 235 is arranged at the second terminal supporting portion 216. The first emitter terminal 235 is electrically connected to the emitter wiring 233. The first emitter terminal 235 includes a first region 240 and a second region 241. The first region 240 of the first emitter terminal 235 is positioned outside the inner space 210. The second region 241 of the first emitter terminal 235 is positioned inside the inner space 210.

The first region 240 of the first emitter terminal 235 is supported by the supporting wall 219 of the second terminal supporting portion 216. The second region 241 of the first emitter terminal 235 penetrates through the side wall 207A from the first region 240 and is led out into the inner space 210. The second region 241 of the first emitter terminal 235 is electrically connected to the emitter wiring 233.

The common terminal 236 is arranged at the third terminal supporting portion 217. The common terminal 236 is electrically connected to the second collector wiring 232. The common terminal 236 includes a first region 242 and a second region 243. The first region 242 of the common terminal 236 is positioned outside the inner space 210. The second region 243 of the common terminal 236 is positioned inside the inner space 210.

The first region 242 of the common terminal 236 is supported by the supporting wall 219 of the second terminal supporting portion 216. The second region 243 of the common terminal 236 penetrates through the side wall 207C from the first region 240 and is led out into the inner space 210. The second region 243 of the common terminal 236 is electrically connected to the second collector wiring 232.

The second emitter terminal 237 is arranged at the fourth terminal supporting portion 218. The second emitter terminal 237 is electrically connected to the emitter wiring 233. The second emitter terminal 237 includes a first region 244 and a second region 245. The first region 244 of the second emitter terminal 237 is positioned outside the inner space 210. The second region 245 of the second emitter terminal 237 is positioned inside the inner space 210.

The first region 244 of the second emitter terminal 237 is supported by the supporting wall 219 of the fourth terminal supporting portion 218. The second region 245 of the second emitter terminal 237 penetrates through the side wall 207C from the first region 244 and is led out into the inner space 210. The second region 245 of the second emitter terminal 237 is electrically connected to the emitter wiring 233.

The semiconductor module 201 includes a plurality of (in this mode, six) side wall terminals 246A to 246H. The plurality of side wall terminals 246A to 246H are arranged in the inner space 210 at an interval along the side wall 207D.

The plurality of side wall terminals 246A to 246H each include an inner connecting portion 247 and an outer connecting portion 248. The inner connecting portion 247 is arranged in the bottom wall 206. The outer connecting portion 248 extends linearly from the inner connecting portion 247 along the side wall 207D and is led out to the outside of the inner space 210.

The plurality of side wall terminals 246A to 246H include four side wall terminals 246A to 246D for the first semiconductor chip 202A and four side wall terminals 246E to 246H for the second semiconductor chip 202B.

The side wall terminals 246A to 246D oppose the first collector wiring 231 along the short direction. The side wall terminal 246A is formed as a gate terminal that is connected to the gate terminal electrode 12 of the first semiconductor chip 202A. The side wall terminals 246B to 246D are each formed, for example, as a terminal that is connected to a current-detecting terminal electrode (not shown) for the first semiconductor chip 202A or others. At least one of the side wall terminals 246B to 246D may be an open terminal.

The side wall terminals 246E to 246H oppose the second collector wiring 232 along the short direction. The side wall terminal 246E is formed as a gate terminal that is connected to the gate terminal electrode 12 of the second semiconductor chip 202B. The side wall terminals 246F to 246H are each formed as a terminal that is connected to a current-detecting terminal electrode (not shown) of the second semiconductor chip 202B, etc. At least one of the side wall terminals 246F to 246H may be an open terminal.

The semiconductor module 201 includes a plurality of conducting wires 249A to 249J. The plurality of conducting wires 249A to 249J may each contain at least one among gold, silver, copper and aluminum. The conducting wires 249A to 249J may each include a bonding wire. The conducting wires 249A to 249J may each include a conductive plate.

The plurality of conducting wires 249A to 249J include a first conducting wire 249A, a second conducting wire 249B, a third conducting wire 249C, a fourth conducting wire 249D, a fifth conducting wire 249E, a sixth conducting wire 249F, a seventh conducting wire 249G, an eighth conducting wire 249H, a ninth conducting wire 249I and a tenth conducting wire 249J.

The first conducting wire 249A connects the collector terminal 234 and the first collector wiring 231. The second conducting wire 249B connects the first emitter terminal 235 and the emitter wiring 233. The third conducting wire 249C connects the common terminal 236 and the second collector wiring 232. The fourth conducting wire 249D connects the second emitter terminal 237 and the emitter wiring 233. The fifth conducting wire 249E connects the emitter terminal electrode 11 and the second collector wiring 232 of the first semiconductor chip 202A. The sixth conducting wire 249F connects the emitter terminal electrode 11 and the emitter wiring 233 of the second semiconductor chip 202B.

The seventh conducting wire 249G connects the gate terminal electrode 12 and the side wall terminal 246A of the first semiconductor chip 202A. The eighth conducting wire 249H connects the gate terminal electrode 12 and the side wall terminal 246E of the second semiconductor chip 202B. The ninth conducting wire 249I connects a current-detecting terminal electrode (not shown) of the first semiconductor chip 202A, etc., and the side wall terminals 246B to 246D. The tenth conducting wire 249J connects a current-detecting terminal electrode (not shown) of the second semiconductor chip 202B, etc., and the side wall terminals 246F to 246H.

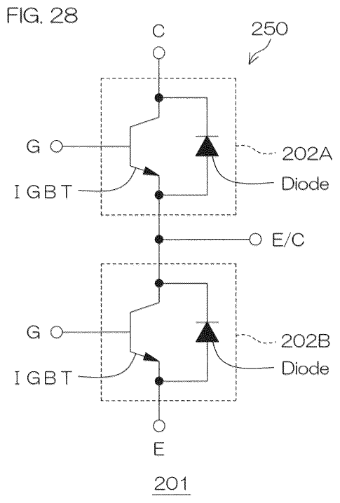

FIG. 28 is a circuit diagram that shows an electrical structure of the semiconductor module 201 in FIG. 27.

With reference to FIG. 28, the semiconductor module 201 includes a half-bridge circuit 250. The half-bridge circuit 250 includes a first semiconductor chip 202A and a second semiconductor chip 202B.

The first semiconductor chip 202A constitutes a high voltage-side arm of the half-bridge circuit 250. The second semiconductor chip 202B constitutes a low voltage-side arm of the half-bridge circuit 250.

The gate terminal (side wall terminal 246A) is connected to the gate terminal electrode 12 of the first semiconductor chip 202A. The collector terminal 234 is connected to the collector terminal electrode 13 of the first semiconductor chip 202A.

The collector terminal electrode 13 of the second semiconductor chip 202B is connected to the emitter terminal electrode 11 of the first semiconductor chip 202A. The common terminal 236 is connected to a connecting portion of the emitter terminal electrode 11 of the first semiconductor chip 202A with the collector terminal electrode 13 of the second semiconductor chip 202B.

The gate terminal (side wall terminal 246D) is connected to the gate terminal electrode 12 of the second semiconductor chip 202B. The first emitter terminal 235 (second emitter terminal 237) is connected to the emitter terminal electrode 11 of the second semiconductor chip 202B.

A gate driver IC, etc., may be connected to the gate terminal electrode 12 of the first semiconductor chip 202A via a gate terminal (side wall terminal 246A). The gate driver IC, etc., may be connected to the gate terminal electrode 12 of the second semiconductor chip 202B via a gate terminal (side wall terminal 246D).

In a three-phase motor having a U phase, a V phase and a W phase, the semiconductor module 201 may be an inverter module that drives any one of the U phase, the V phase and the W phase. An inverter device that drives a three-phase motor may be constituted of the three semiconductor modules 201 which correspond to the U phase, the V phase and the W phase of the three-phase motor.

In this case, a direct-current power supply is connected to the collector terminal 234 and the first emitter terminal 235 (second emitter terminal 237) of each of the semiconductor modules 201. Also, any one of the U phase, the V phase and the W phase of the three-phase motor is connected as a load to the common terminal 236 of each of the semiconductor modules 201.

In the inverter device, the first semiconductor chip 202A and the second semiconductor chip 202B are driven and controlled by a predetermined switching pattern. Thereby, a dc voltage is converted to a three-phase ac voltage, and the three-phase motor is sine-wave driven.

A description has been given of the preferred embodiments of the present disclosure, and the present disclosure can also be implemented in other modes.

For example, in the aforementioned preferred embodiments, there may be adopted a structure in which a conductivity type of each semiconductor portion is inverted. That is, a p-type portion may be formed as an n-type and an n-type portion may be formed as a p-type.

Also, as an example of the field limit region 61, the p-type impurity region that is formed by introducing a p-type impurity into the semiconductor chip 16 has been described. However, for example, a trench is formed in the first principal surface 17 of the semiconductor chip 16 and an embedded conductive layer (conductive polysilicon, etc.) embedded in the trench via an insulating layer may be formed as the field limit region 61. In this case, the p-type impurity region may be formed along an inner surface of the trench.

Also, as the first semiconductor chip 202A and the second semiconductor chip 202B that are mounted on the semiconductor module 201 shown in FIG. 27, the element chip 10 having a MOSFET structure may be applied as an FET structure.

As described so far, the preferred embodiments of the present disclosure are merely examples in every respect and should not be interpreted as being limited, and the examples are intended to be modified in every respect.

The following features can be extracted from the present description and the drawings.

### APPENDIX 1-1

A semiconductor device (1) including a semiconductor chip (16) having a first principal surface (17) in which an element forming region (20) that includes an element structure (42, 112, 124) is formed,
a withstand-voltage holding structure (59, 60, 61) that is formed at a peripheral region (21) around the element forming region (20) in the first principal surface (17) of the semiconductor chip (16) and holds a withstand voltage of the element structure (42, 112, 124),
an interlayer insulating layer (66) that is formed in the first principal surface (17) of the semiconductor chip (16),
a plurality of first conductive layers (23, 24, 34, 132) that are formed at an interval from each other on the first principal surface (17), and the plurality of first conductive layers (23, 24, 34, 132) that pass through the interlayer insulating layer (66) and are connected to the withstand-voltage holding structure (59, 60, 61),
a second conductive layer (83, 133) that is insulated from the semiconductor chip (16) by the interlayer insulating layer (66) and overlaps with a space (82, 134) between the plurality of first conductive layers (23, 24, 34, 132) that are adjacent to each other in a plan view, and
a protective layer (80) that is formed on the interlayer insulating layer (66) so as to cover the plurality of first conductive layers (23, 24, 34, 132) and the second conductive layer (83, 133).

### APPENDIX 1-2

The semiconductor device (1) according to Appendix 1-1, in which the second conductive layer (83, 133) includes an embedded conductive layer that is embedded in the interlayer insulating layer (66), and
the embedded conductive layer opposes a space (82, 134) between the plurality of first conductive layers (23, 24, 34, 132) in a thickness direction of the interlayer insulating layer (66).

### APPENDIX 1-2-1

The semiconductor device (1) according to Appendix 1-2, in which the first conductive layer (23, 24, 34, 132) includes a contact portion (84) that is provided in a contact hole (75) formed in the interlayer insulating layer (66) and that is connected to the withstand-voltage holding structure (59, 60, 61), a first lead-out portion (101) that is led out toward the embedded conductive layer from a middle portion of the contact portion (84) in a depth direction of the contact hole (75), and a second lead-out portion (102) that is led out along a front surface of the interlayer insulating layer (66) from an upper end portion of the contact portion (84).

### APPENDIX 1-2-2

The semiconductor device (1) according to Appendix 1-2-1, in which a distance (D2) from a circumferential surface of the contact portion (84) to a horizontal-direction end portion of the second lead-out portion (102) is longer than a distance (D1) from a circumferential surface of the contact portion (84) to a horizontal-direction end portion of the first lead-out portion (101).

### APPENDIX 1-2-3

The semiconductor device (1) according to Appendix 1-2-1 or Appendix 1-2-2, in which one and the other of the mutually adjacent first conductive layers (23, 24, 34, 132) each have the second lead-out portion (102), and the one and the other second lead-out portions (102) oppose each other at an interval of a second interval (W2) on the front surface of the interlayer insulating layer (66), and
a first interval (W1) between the first lead-out portion (101) of the one first conductive layer (23, 24, 34, 132) and the embedded conductive layer is narrower than the second interval (W2) between the one second lead-out portion (102) and the other second lead-out portion (102).

### APPENDIX 1-2-4

The semiconductor device (1) according to Appendix 1-2-3, in which the first interval (W1) is not less than 1 μm and the second interval (W2) is not less than 10 μm.

### APPENDIX 1-2-5

The semiconductor device (1) according to Appendix 1-2, in which the interlayer insulating layer (66) includes a first portion (86) having a first thickness (T1) that is further at the semiconductor chip (16) side than the embedded conductive layer and a second portion (87) that is formed on the first portion (86), covers the embedded conductive layer and also has a second thickness (T2) thinner than the first thickness (T1).

### APPENDIX 1-2-6

The semiconductor device (1) according to Appendix 1-2-5, in which the first thickness (T1) is not less than 3000 Å and not more than 20000 Å, and the second thickness (T2) is not less than 1000 Å and not more than 10000 Å.

### APPENDIX 1-3

The semiconductor device (1) according to Appendix 1-2, in which the first conductive layer (23, 24, 34, 132) includes a surface layer portion (85) that is formed on the interlayer insulating layer (66) and a contact portion (84) that passes from the surface layer portion (85) through the interlayer insulating layer (66) and is connected to the withstand-voltage holding structure (59, 60, 61), and the embedded conductive layer opposes a part of the surface layer portion (85) of the first conductive layer (23, 24, 34, 132) in a thickness direction of the interlayer insulating layer (66).

### APPENDIX 1-4

The semiconductor device (1) according to Appendix 1-2, in which the first conductive layer (23, 24, 34, 132) includes a contact portion (84) that is provided in a contact hole (75) formed in the interlayer insulating layer (66) and connected to the withstand-voltage holding structure (59, 60, 61) and an overlap portion (102) that is led out on the front surface of the interlayer insulating layer (66) from the contact portion (84) and overlaps with the embedded conductive layer in a plan view.

### APPENDIX 1-5

The semiconductor device (1) according to Appendix 1-3 or Appendix 1-4, in which the interlayer insulating layer (66) includes a first portion (86) that is further at the semiconductor chip (16) side than the embedded conductive layer and a second portion (87) that is formed on the first portion (86) and covers the embedded conductive layer, and the contact portion (84) of the first conductive layer (23, 24, 34, 132) further includes a protrusion portion (100) that selectively protrudes in a region on the first portion (86) toward the embedded conductive layer.

### APPENDIX 1-5-1

The semiconductor device (1) according to Appendix 1-5, in which the first portion (86) of the interlayer insulating layer (66) has a first thickness (T1), and the second portion (87) of the interlayer insulating layer (66) has a second thickness (T2) that is thinner than the first thickness (T1).

### APPENDIX 1-5-2

The semiconductor device (1) according to Appendix 1-5-1, in which the first thickness (T1) is not less than 3000 Å and not more than 20000 Å, and the second thickness (T2) is not less than 1000 Å and not more than 10000 Å.

### APPENDIX 1-6

The semiconductor device (1) according to any one of Appendix 1-2 to Appendix 1-4, in which the interlayer insulating layer (66) includes a first portion (86) that is further at the semiconductor chip (16) side than the embedded conductive layer and a second portion (87) that is formed on the first portion (86) and covers the embedded conductive layer, and
the contact portion (84) includes a first embedded portion (92) that is formed by a barrier layer (94) and a contact plug (95) embedded in the first portion (86) of the interlayer insulating layer (66) via the barrier layer (94) and a second embedded portion (93) that is embedded in the second portion (87) of the interlayer insulating layer (66) and formed by a conductive material different from the contact plug (95).

### APPENDIX 1-6-1

The semiconductor device (1) according to Appendix 1-6, in which the contact plug (95) includes a tungsten plug, and the second embedded portion (93) includes an aluminum-based metal.

### APPENDIX 1-7

The semiconductor device (1) according to any one of Appendix 1-2 to Appendix 1-4, in which the interlayer insulating layer (66) includes a first portion (86) that is further at the semiconductor chip (16) side than the embedded conductive layer and a second portion (87) that is formed on the first portion (86) and covers the embedded conductive layer, and
the contact portion (84) includes an embedded contact that includes an embedded portion (110, 122) that is formed by a single conductive material integrally embedded in the first portion (86) and the second portion (87) of the interlayer insulating layer (66) and a barrier layer (94) that is formed between the first portion (86) and the embedded portion (110, 122).

### APPENDIX 1-7-1

The semiconductor device (1) according to Appendix 1-7, in which the barrier layer (94) contains a titanium-based metal, and the embedded portion (110, 122) contains an aluminum-based metal.

### APPENDIX 1-8

The semiconductor device (1) according to any one of Appendix 1-2 to Appendix 1-4, in which the interlayer insulating layer (66) includes a first portion (86) that is further at the semiconductor chip (16) side than the embedded conductive layer and a second portion (87) that is formed on the first portion (86) and covers the embedded conductive layer, and
the contact portion (84) includes an embedded contact (110, 122) that is formed by a single conductive material integrally embedded in the first portion (86) and the second portion (87) of the interlayer insulating layer (66) and that is directly connected to the withstand-voltage holding structure (59, 60, 61).

### APPENDIX 1-8-1

The semiconductor device (1) according to Appendix 1-8, in which the element structure (42, 112, 124) includes a diode structure (112, 124).

### APPENDIX 1-8-2

The semiconductor device (1) according to Appendix 1-8-1, in which the diode structure (112, 124) includes a fast recovery diode.

### APPENDIX 1-8-3

The semiconductor device (1) according to Appendix 1-8 or Appendix 1-8-1, in which the embedded contact contains an aluminum-based metal.

### APPENDIX 1-9

The semiconductor device (1) according to any one of Appendix 1-1 to Appendix 1-8, in which an active thickness (TA) of the interlayer insulating layer (66) in the element forming region (20) is thinner than a peripheral thickness (TC) of the interlayer insulating layer (66) in the peripheral region (21).

### APPENDIX 1-9-1

The semiconductor device (1) according to Appendix 1-5-1, in which the active thickness (TA) is not less than 3000 Å and not more than 20000 Å, and the peripheral thickness (TC) is not less than 4000 Å and not more than 30000 Å.

### APPENDIX 1-10

The semiconductor device (1) according to any one of Appendix 1-1 to Appendix 1-9, in which a step (70) is formed at a boundary portion (69) between the element forming region (20) and the peripheral region (21) in the front surface of the interlayer insulating layer (66).

### APPENDIX 1-11

The semiconductor device (1) according to any one of Appendix 1-1 to Appendix 1-11 including a first output electrode (11, 116, 128, 137) that is exposed from the protective layer (80) in the element forming region (20) and connected to the element structure (42, 112, 124), in which
a height from the first principal surface (17) of the semiconductor chip (16) to a front surface (H2) of the first conductive layer (23, 24, 34, 132) is higher than a height (H1) from the first principal surface (17) of the semiconductor chip (16) to the first output electrode (11, 116, 128, 137).

### APPENDIX 1-12

The semiconductor device (1) according to Appendix 1-1, in which the plurality of first conductive layers (23, 24, 34, 132) and the second conductive layer (83, 133) are both formed on the interlayer insulating layer (66), and
the second conductive layer (83, 133) is provided at a space (82, 134) between the plurality of first conductive layers (23, 24, 34, 132) in the front surface of the interlayer insulating layer (66).

### APPENDIX 1-13

The semiconductor device (1) according to Appendix 1-12, further including a LOCOS (Local oxidation of silicon) oxide film (62) that is formed in a region held between the plurality of withstand-voltage holding structures (59, 60, 61) in the first principal surface (17) of the semiconductor chip (16), in which
the first conductive layer (23, 24, 34, 132) is provided at a position directly on the withstand-voltage holding structure (59, 60, 61), and
the second conductive layer (83, 133) is provided at a position directly on the LOCOS oxide film (62).

### APPENDIX 1-14

The semiconductor device (1) according to any one of Appendix 1-1 to Appendix 1-13, in which a space (82, 134) between the plurality of first conductive layers (23, 24, 34, 132) is formed linearly in a plan view, and the second conductive layer (83, 133) is formed linearly in a plan view so as to extend along the linear space (82, 134).

### APPENDIX 1-14-1

The semiconductor device (1) according to Appendix 1-14, in which the space (82, 134) between the plurality of first conductive layers (23, 24, 34, 132) is formed in an endless annular shape that surrounds the element forming region (20) in a plan view, and
the second conductive layer (83, 133) is formed in an endless annular shape in a plan view that extends along the space (82, 134) in the endless annular shape.

### APPENDIX 1-15

The semiconductor device (1) according to any one of Appendix 1-1 to Appendix 1-14, in which the peripheral region (21) includes an outer region (21) that surrounds the element forming region (20) and is formed at a peripheral end portion of the semiconductor chip (16).

### APPENDIX 1-16

The semiconductor device (1) according to any one of Appendix 1-1 to Appendix 1-15, in which the semiconductor chip (16) includes a first conductivity type first impurity region (38) that is formed at the first principal surface (17) side, and
the withstand-voltage holding structure (59, 60, 61) includes a second impurity region that is formed by introducing a second conductivity type impurity into the first impurity region (38).

### APPENDIX 1-17

The semiconductor device (1) according to Appendix 1-16, in which the withstand-voltage holding structure (59, 60, 61) includes at least one of an FLR (Field Limiting Ring) structure (61) and a RESURF (Reduced Surface Field) layer (60) that surround the element forming region (20).

### APPENDIX 1-18

The semiconductor device (1) according to any one of Appendix 1-1 to Appendix 1-17, in which the element structure (42, 112, 124) includes at least one of an IGBT (Insulated Gate Bipolar Transistor) structure, a diode structure and a MOSFET (Metal Oxide Semiconductor Field Effect Transistor) structure.

### APPENDIX 1-19

The semiconductor device (1) according to any one of Appendix 1-1 to Appendix 1-18, in which the protective layer (80) is formed of a polyimide resin or a PBO (Polybenzoxazole) resin.

### APPENDIX 1-20

The semiconductor device (1) according to any one of Appendix 1-1 to Appendix 1-19 which is a discrete semiconductor that includes a sealing resin (2) for sealing the semiconductor chip (16).

### APPENDIX 1-21

A semiconductor module (201) including a resin-made housing (203) and a plurality of semiconductor devices (1) that are installed in the housing (203) and include at least one semiconductor device (1) according to any one of Appendix 1-1 to Appendix 1-19.

### APPENDIX 1-22

The semiconductor device (1) according to Appendix 1-1 including the plurality of withstand-voltage holding structures (59, 60, 61) that are formed at an interval from each other, in which
the second conductive layer (83, 133) includes a sealing conductive layer (83) that seals from the opposite side of the semiconductor layer (16) a portion of the interlayer insulating layer (66) that encompasses the plurality of mutually adjacent withstand-voltage holding structures (59, 60, 61).

### APPENDIX 2-1

A semiconductor device (1) including a first conductivity type semiconductor layer (16) having a first principal surface (17) in which an element forming region (20) that includes an element structure (42, 112, 124) is formed,
a plurality of withstand-voltage holding structures (59, 60, 61) that include a second conductivity type impurity region formed in an outer region (21) around the element forming region (20) in the first principal surface (17) of the semiconductor layer (16) and that are formed at an interval from each other,
an interlayer insulating layer (62, 66) that is formed in the first principal surface (17) of the semiconductor chip (16),
a front surface metal (23) that is formed at a front surface of the interlayer insulating layer (62, 66), and the front surface metal (23) including a plurality of outer circumference electrode metals (23, 24, 34, 132), each of which is connected to the plurality of withstand-voltage holding structures (59, 60, 61) through the interlayer insulating layer (62, 66),
a sealing metal (83, 133) that seals from the opposite side of the semiconductor layer (16) a portion of the interlayer insulating layer (62, 66) that encompasses the plurality of adjacent withstand-voltage holding structures (59, 60, 61), and the sealing metal (83, 133) that is embedded in the interlayer insulating layer (62, 66) and partially opposes the outer circumference electrode metal (23, 24, 34, 132) in a thickness direction of the interlayer insulating layer (62, 66), and
a protective layer (80) that is formed on the interlayer insulating layer (62, 66) so as to cover the front surface metal (23).

### APPENDIX 2-2

The semiconductor device (1) according to Appendix 2-1, in which the outer circumference electrode metal (23, 24, 34, 132) includes a contact portion (84) that is provided at a contact hole (75) formed in the interlayer insulating layer (62, 66) and connected to the withstand-voltage holding structure (59, 60, 61) and an overlap portion (102) that is led out onto the front surface of the interlayer insulating layer (62, 66) from the contact portion (84) and overlaps with the sealing metal (83, 133) in a plan view.

### APPENDIX 2-3

The semiconductor device (1) according to Appendix 2-2, in which the contact portion (84) of the outer circumference electrode metal (23, 24, 34, 132) further includes an extension portion (100) that selectively extends along the first principal surface (17) toward the sealing metal (83, 133).

### APPENDIX 2-4

The semiconductor device (1) according to any one of Appendix 2-1 to Appendix 2-3, in which the portion of the interlayer insulating layer (66) that encompasses the plurality of adjacent withstand-voltage holding structures (59, 60, 61) includes a thermal oxide film (62) that is partially embedded in the first principal surface (17) and a deposited oxide film (66) on the thermal oxide film, and
the sealing metal (83, 133) is provided at the front surface of the deposited oxide film (66).

### APPENDIX 2-5

The semiconductor device (1) according to Appendix 2-4, in which the deposited oxide film (66) has a thickness (T1, T2) that is greater than the thickness (TF) of the thermal oxide film (62).

1. A semiconductor device comprising:
a semiconductor chip having a first principal surface in which an element forming region that includes an element structure is formed;
a withstand-voltage holding structure that is formed in a peripheral region around the element forming region in the first principal surface of the semiconductor chip and holds a withstand voltage of the element structure;
an interlayer insulating layer that is formed in the first principal surface of the semiconductor chip;
a plurality of first conductive layers that are formed at an interval from each other on the first principal surface, and the plurality of first conductive layers that pass through the interlayer insulating layer and are connected to the withstand-voltage holding structure;
a second conductive layer that is insulated from the semiconductor chip by the interlayer insulating layer and overlaps with a space between the plurality of mutually adjacent first conductive layers in a plan view; and
a protective layer that is formed on the interlayer insulating layer so as to cover the plurality of first conductive layers and the second conductive layer.

2. The semiconductor device according to claim 1, wherein
the second conductive layer includes an embedded conductive layer that is embedded in the interlayer insulating layer, and
the embedded conductive layer opposes a space between the plurality of first conductive layers in a thickness direction of the interlayer insulating layer.

3. The semiconductor device according to claim 2, wherein
the first conductive layer includes a surface layer portion that is formed on the interlayer insulating layer and a contact portion that passes from the surface layer portion through the interlayer insulating layer and is connected to the withstand-voltage holding structure, and
the embedded conductive layer opposes a part of the surface layer portion of the first conductive layer in a thickness direction of the interlayer insulating layer.

4. The semiconductor device according to claim 2, wherein
the first conductive layer includes a contact portion that is provided at a contact hole formed in the interlayer insulating layer and connected to the withstand-voltage holding structure and an overlap portion that is led out onto a front surface of the interlayer insulating layer from the contact portion and overlaps with the embedded conductive layer in a plan view.

5. The semiconductor device according to claim 3, wherein
the interlayer insulating layer includes a first portion that is further at the semiconductor chip side than the embedded conductive layer and a second portion that is formed on the first portion and covers the embedded conductive layer, and
the contact portion of the first conductive layer further includes a protrusion portion that selectively protrudes in a region on the first portion toward the embedded conductive layer.

6. The semiconductor device according to claim 2, wherein
the interlayer insulating layer includes a first portion that is further at the semiconductor chip side than the embedded conductive layer and a second portion that is formed on the first portion and covers the embedded conductive layer, and
the contact portion includes a first embedded portion that is formed by a barrier layer and a contact plug embedded in the first portion of the interlayer insulating layer via the barrier layer and the barrier layer and a second embedded portion that is embedded in the second portion of the interlayer insulating layer and formed of a conductive material different from the contact plug.

7. The semiconductor device according to claim 2, wherein
the interlayer insulating layer includes a first portion that is further at the semiconductor chip side than the embedded conductive layer and a second portion that is formed on the first portion and covers the embedded conductive layer, and
the contact portion includes an embedded portion that is formed of a single conductive material integrally embedded in the first portion and the second portion of the interlayer insulating layer and an embedded contact that includes a barrier layer formed between the first portion and the embedded portion.

8. The semiconductor device according to claim 2, wherein
the interlayer insulating layer includes a first portion that is further at the semiconductor chip side than the embedded conductive layer and a second portion that is formed on the first portion and covers the embedded conductive layer, and
the contact portion includes an embedded contact that is formed of a single conductive material integrally embedded in the first portion and the second portion of the interlayer insulating layer and directly connected to the withstand-voltage holding structure.

9. The semiconductor device according to claim 1, wherein
a thickness of the interlayer insulating layer in the element forming region is thinner than the thickness of the interlayer insulating layer in the peripheral region.

10. The semiconductor device according to claim 1, wherein
in the front surface of the interlayer insulating layer, a step is formed at a boundary portion between the element forming region and the peripheral region.

11. The semiconductor device according to claim 1 including a first output electrode that is exposed from the protective layer in the element forming region and connected to the element structure, wherein
a height from the first principal surface of the semiconductor chip to a front surface of the first conductive layer is higher than a height from the first principal surface of the semiconductor chip to the first output electrode.

12. The semiconductor device according to claim 1, wherein
the plurality of first conductive layers and the second conductive layer are both formed on the interlayer insulating layer, and
the second conductive layer is provided at a space between the plurality of first conductive layers in the front surface of the interlayer insulating layer.

13. The semiconductor device according to claim 12 further including a LOCOS (Local oxidation of silicon) oxide film that is formed in a region held between the plurality of withstand-voltage holding structures in the first principal surface of the semiconductor chip, wherein
the first conductive layer is provided at a position directly on the withstand-voltage holding structure, and
the second conductive layer is provided at a position directly on the LOCOS oxide film.

14. The semiconductor device according to claim 1, wherein
a space between the plurality of first conductive layers is formed linearly in a plan view, and
the second conductive layer is formed linearly in a plan view so as to extend along the space that is formed linearly.

15. The semiconductor device according to claim 1, wherein the peripheral region includes an outer region that surrounds the element forming region and is formed at a peripheral end portion of the semiconductor chip.

16. The semiconductor device according to claim 1, wherein
the semiconductor chip includes a first conductivity type first impurity region that is formed at the first principal surface side, and
the withstand-voltage holding structure includes a second impurity region that is formed by introducing a second conductivity type impurity into the first impurity region.

17. The semiconductor device according to claim 16, wherein
the withstand-voltage holding structure includes at least one of an FLR (Field Limiting Ring) structure and a RESURF (Reduced Surface Field) layer that surround the element forming region.

18. The semiconductor device according to claim 1, wherein
the element structure includes at least one of an IGBT (Insulated Gate Bipolar Transistor) structure, a diode structure and a MOSFET (Metal Oxide Semiconductor Field Effect Transistor) structure.

19. The semiconductor device according to claim 1 which is a discrete semiconductor that includes a sealing resin for sealing the semiconductor chip.

20. A semiconductor module comprising:
a resin-made housing; and
a plurality of semiconductor devices that are installed in the housing and include at least one of the semiconductor devices according to claim 1.
